(19) United States
(12) Patent Application Publication
(10) Pub. No.: US 2015/0009624 A1
(43) Pub. Date: Jan. 8, 2015

(54) STACKABLE COOLING RAIL BASED SYSTEM

(71) Applicant: BIRCHBRIDGE INCORPORATED, Belmont, CA (US)

(72) Inventors: John Craig Dunwoody, Belmont, CA (US); Teresa Ann Dunwoody, Belmont, CA (US)

(21) Appl. No.: 13/937,145

(22) Filed: Jul. 8, 2013

(51) Int. Cl. H05K 7/20; F28F 9/007

(52) U.S. Cl. CPC H05K 7/20536; F28F 9/007
USPC 361/688; 165/67

(57) ABSTRACT

Systems and methods providing for packaging of scalable machines are discussed herein. Some embodiments may include a stackable cooling rail based system with a plurality of stackable frames. A stackable frame may contain one or more modules that may contain functional components; one or more cooling elements to remove heat from the one or more modules (e.g., on a first side); and one or more cooling rails coupled thermally with the one or more cooling elements. The stackable frame may move (e.g., together) with at least one of its cooling rails, such that the stackable frames and cooling rails may be adjustable between an opened configuration and a stacked configuration. In the opened configuration, an access gap may be present between a pair of consecutively stacked stackable frames and their cooling rails, to provide physical access to modules and other features.

### FIELD

Embodiments of the invention relate, generally, to packaging for scalable machines.

### BACKGROUND

Circuitry can be configured to provide data networking, processing, storage, and/or other types of functionality. Often, such circuitry, referred to herein as “components,” is installed in computing racks that provide packaging, power, networking and cooling to the computing components. The design of rack based computing systems may require various tradeoffs in areas such as space efficiency (e.g., usable networking, processing, and/or storage capacity per unit of volume and/or floor area occupied by a computing rack), energy efficiency, cost, scalability, and serviceability. In this regard, areas for improving current systems have been identified.

### BRIEF SUMMARY

Through applied effort, ingenuity, and innovation, solutions to improve packaging of scalable machines that may perform data-related functions and/or other types of functions, have been realized and are described herein. More specifically, an alternative packaging approach for such machines, which does not involve racks, has been identified. This alternative packaging approach may be superior in areas such as space efficiency (e.g., quantity of usable data networking, processing, storage, and/or other functional capacity per unit of volume and/or floor area); energy efficiency; manufacturing cost; scalability; and serviceability. In accordance with this alternative packaging approach, systems and methods providing for packaging of scalable machines are discussed herein.

In some embodiments, the packaging may include one or more cooling rails, and may be referred to herein as a stackable cooling rail based system. The stackable cooling rail based system may include a plurality of stackable frames. Each of the stackable frames may include one or more frame spacers; a module receiving area; a cooling element configured to couple thermally with one of a first side and a second side of a module when the module is located in the module receiving area; and one or more cooling rails coupled thermally with the cooling element.

In some embodiments, the plurality of stackable frames may be disposed along a stacking axis. Each of the plurality of stackable frames may be configured to occupy a fixed distance (referred to herein as the “stacking size”) along the stacking axis when stacked, such that the stacking size may be greater than or equal to a minimum stacking pitch P. Each of the plurality of stackable frames may further be configured such that along the stacking axis, the stacking size may be determined by the collective physical extent of the one or more frame spacers, and the collective physical extent of all of the other parts of the stackable frame, including the module receiving area, cooling element, and one or more cooling rails, may fit entirely within the collective physical extent of the one or more frame spacers.

In some embodiments, the plurality of stackable frames may be adjustable (e.g., along the stacking axis) between a stacked configuration and an opened configuration. In the stacked configuration, the plurality of stackable frames may be stacked together. In the opened configuration, at least one pair of consecutively stacked stackable frames, selected from the plurality of stackable frames, may be separated by an access gap. For example, the access gap may be configured to provide physical access to a module.

In some embodiments, each of the one or more cooling rails of each stackable frame may include one or more fluid channels for cooling fluid flow. Each of the one or more cooling rails of each stackable frame may further include a slot for thermal coupling with the cooling element of each stackable frame. Furthermore, the one or more cooling rails of each stackable frame may each conform to a distance defined by their stackable frame. For example, along the stacking axis, for each of the plurality of stackable frames, the collective physical extent of the one or more cooling rails of the stackable frame may be configured to conform to the collective physical extent of the one or more frame spacers of the stackable frame. In some embodiments, the one or more cooling rails of each of the plurality of stackable frames may include a first cooling rail and a second cooling rail coupled thermally with the cooling element at opposite sides of the cooling element.

In some embodiments, the cooling element of each stackable frame may be a vapor chamber. The vapor chamber may include a planar profile or a non-planar profile. In some embodiments, each of the plurality of stackable frames may further include a second cooling element coupled thermally with the one of the first side and the second side of the module, and with the one or more cooling rails.

In some embodiments, the stackable cooling rail based system may further include an inlet cooling fluid manifold to provide cooling fluid to at least one of the one or more cooling rails of each stackable frame. The inlet cooling fluid manifold may be connected with the at least one of the one or more cooling rails via a flexible connection. Furthermore, the stackable cooling rail based system may include an outlet cooling fluid manifold to receive cooling fluid from at least one of the one or more cooling rails of each stackable frame. The outlet cooling fluid manifold may be connected with the at least one of the one or more cooling rails via a flexible connection.

In some embodiments, the stackable cooling rail based system may further include one or more modules. Each module may include one or more printed circuit board assemblies that may collectively define an outer surface of the module on at least one of a first side and a second side of the module. Each such printed circuit board assembly may have components disposed on two sides of its printed circuit board, or alternatively, on one side only.

In some embodiments, the stackable cooling rail based system may further include one or more chassis, each including one or more chassis poles that may each be disposed substantially parallel to the stacking axis. Each of the one or more frame spacers of each stackable frame may include a chassis pole hole to receive a chassis pole of the one or more chassis poles. The one or more cooling rails of each stackable frame may move together with their stackable frame along the stacking axis.

Some embodiments may provide for a stackable cooling rail based system including a plurality of stackable frames. At least one stackable frame may include: a frame defining a module receiving area; one or more vapor chambers coupled mechanically with the at least one stackable frame for thermal coupling with one or more modules located in the module receiving area; and one or more cooling rails coupled thermally with the one or more vapor chambers and coupled mechanically with the at least one stackable frame such that the one or more cooling rails is configured to move together with the at least one stackable frame. Furthermore, the plurality of stackable frames may be adjustable between a stacked configuration and an opened configuration. In the stacked configuration, the plurality of stackable frames may be stacked together. In the opened configuration, at least one pair of consecutively stacked stackable frames, selected from the plurality of stackable frames, may be separated by an access gap.

In some embodiments, the collective physical extent of at least one of the one or more cooling rails of the at least one stackable frame may be configured to conform (e.g., along the stacking axis) to the collective physical extent of the module receiving area and at least one of the one or more vapor chambers. Furthermore, at least one of the one or more cooling rails of the at least one stackable frame may include one or more fluid channels for cooling fluid flow.

Some embodiments may provide for a stackable cooling rail based system including a plurality of stackable frames, one or more inlet cooling fluid manifolds, and one or more outlet cooling fluid manifolds. At least one of the stackable frames may include: one or more modules, at least one module including one or more printed circuit board assemblies that collectively define at least one of a first and second outer surface of the at least one module, and each of the printed circuit board assemblies having components disposed on one or more sides; one or more vapor chambers coupled thermally with one of a first side and a second side of at least one of the one or more modules; and one or more cooling rails coupled thermally with at least one of the one or more vapor chambers. The one or more inlet cooling fluid manifolds may provide cooling fluid to at least one of the one or more cooling rails of the at least one stackable frame. The one or more outlet cooling fluid manifolds may receive cooling fluid from the at least one of the one or more cooling rails of the at least one stackable frame. In some embodiments, at least one of the one or more cooling rails of the at least one stackable frame may be configured to conform to a distance defined by a combined thickness of at least one of the one or more modules of the at least one stackable frame and at least one of the one or more vapor chambers of the at least one stackable frame.

These characteristics, as well as additional features, functions, and details of various corresponding and additional embodiments, are also described below.

### BRIEF DESCRIPTION OF THE DRAWINGS

Having thus described some embodiments in general terms, reference will now be made to the accompanying drawings, which are not necessarily drawn to scale, and wherein:

FIG. 1A shows a front view of an example stackable cooling rail based system, in accordance with some embodiments;

FIG. 1B shows a back view of an example stackable cooling rail based system, in accordance with some embodiments;

FIG. 1C shows a side view of an example stackable cooling rail based system, in accordance with some embodiments;

FIG. 2 shows a cross sectional top view of an example stackable cooling rail based system, in accordance with some embodiments;

FIGS. 3A and 3B each show cross sectional views of an example stackable frame, in accordance with some embodiments;

FIG. 4 shows an example stackable frame, in accordance with some embodiments;

FIGS. 5A and 5B show an example network module, configured in accordance with some embodiments;

FIGS. 6A and 6B show a front view and a side view, respectively, of an example stackable cooling rail based system in an opened configuration, in accordance with some embodiments;

FIG. 7 shows an example stackable frame and chassis poles, in accordance with some embodiments;

FIG. 8 shows another example of a stackable frame, in accordance with some embodiments;

FIG. 9 shows a cross sectional top view of an example stackable cooling rail based system, in accordance with some embodiments;

FIGS. 10A and 10B show example frame spacers, in accordance with some embodiments;

FIG. 11 shows an example module, in accordance with some embodiments;

FIGS. 12A and 12B show an example boat lobe board of a module, in accordance with some embodiments;

FIG. 13 shows a cross sectional top view of an example stackable cooling rail based system, in accordance with some embodiments;

FIG. 14 shows an example module, in accordance with some embodiments; and

FIG. 15 shows a cross sectional top view of an example stackable cooling rail based system, in accordance with some embodiments.

### DETAILED DESCRIPTION

Embodiments will be described more fully hereinafter with reference to the accompanying drawings, in which some, but not all embodiments contemplated herein are shown. Indeed, various embodiments may be implemented in many different forms and should not be construed as limited to the embodiments set forth herein; rather, these embodiments are provided so that this disclosure will satisfy applicable legal requirements. Like numbers refer to like elements throughout.

Some embodiments discussed herein may provide for a stackable cooling rail based system. The stackable cooling rail based system may provide for scalable machine packaging, and may be one example of scalable packaging. For example, the stackable cooling rail based system may contain functional components (e.g., in groups of components, referred to herein as “modules”) that are interconnected to perform a set of functions including but not limited to one or more of the following: data creation, data communication/networking, data processing, and data storage. In some embodiments, the functional components may collectively include one or more basic data-machine elements such as data-producing sensors, data processing elements, volatile and/or nonvolatile data storage/memory elements, data network switching/routing elements, or the like. In some embodiments, these functional components may include units that integrate multiple types of data-machine elements (e.g., System-on-Chip (SoC) units). The stackable cooling rail based system may be configured to provide packaging for the functional components in a scalable and space efficient manner, while also efficiently delivering to these components a set of services that may include, without limitation, one or more of the following: mechanical support and/or protection, energy input and/or output connection, heat removal, and data input and/or output connection.

In some embodiments, the stackable cooling rail based system may include a plurality of interconnected chassis, each including a plurality of stackable frames. At least one of these stackable frames may house one or more modules. During the course of operation, a plurality of stackable frames of a chassis may be stacked together in a “stacked configuration,” as used herein, such that modules within these stackable frames receive two-sided cooling. This cooling may be provided by any suitable means. For example, one or more cooling elements such as vapor chambers and/or similar structures may be coupled with at least one of the stackable frames, to provide module cooling from a first side (e.g., the bottom). Here, a module of a stackable frame may be cooled from a second side (e.g., the top) by an adjacently stacked stackable frame.

Some embodiments may provide for enhanced serviceability and space efficiency. For example, the stackable cooling rail based system may be configured such that an access gap may be held open between a selectable pair of consecutively stacked stackable frames. An “opened configuration,” as used herein, refers to a configuration of the system where at least one selectable pair of consecutively stacked stackable frames are separated by an access gap. This gap may be used to provide access to one or more modules, power and networking connections, cooling elements, components of one or more modules, etc. for tasks such as installation, repair, replacement, removal, configuration, reconfiguration, troubleshooting, upgrades, or the like. After completion of such tasks, the stackable rack-based computing system may be reconfigured into the stacked configuration such that the access gap may be closed, so that the stackable frames are stacked together (e.g., to provide two-sided cooling to the modules). In some embodiments, the stackable frames may be configured to facilitate addition or removal of individual stackable frames as desired (e.g., to increase and/or decrease the number of modules that the chassis can contain).

In some embodiments, at least one of the stackable frames may further include one or more cooling rails. These one or more cooling rails may be coupled thermally with the one or more cooling elements, to remove heat from the one or more cooling elements. Furthermore, the one or more cooling rails may be coupled mechanically with its stackable frame, to move with its stackable frame (e.g., during transitions between stacked and opened configurations). In some embodiments, the stackable cooling rail based system may include one or more inlet cooling fluid manifolds and one or more outlet cooling fluid manifolds. For example, an inlet cooling fluid manifold may provide cooling fluid (e.g., water and/or any suitable combination of liquid and/or gas) to at least one of the one or more cooling rails of the at least one stackable frame. The outlet cooling fluid manifold may receive cooling fluid from the at least one of the one or more cooling rails of the at least one stackable frame.

Some embodiments may further provide for modules having components that are disposed and/or interconnected for space efficiency, two-sided cooling, and serviceability. For example, a module may include one or more printed circuit board assemblies (PCBAs) having components disposed on two sides. In the stacked configuration, components on a first side of the PCBA may couple thermally and/or mechanically with a first cooling element, and components on a second side of the PCBA may couple thermally and/or mechanically with a second cooling element. The resulting stacked, repeating configuration of cooling element, components, printed circuit board, components, and cooling element, may provide two-sided cooling to the modules at the PCBA level in a space-efficient manner, allowing for greater component density within the chassis.

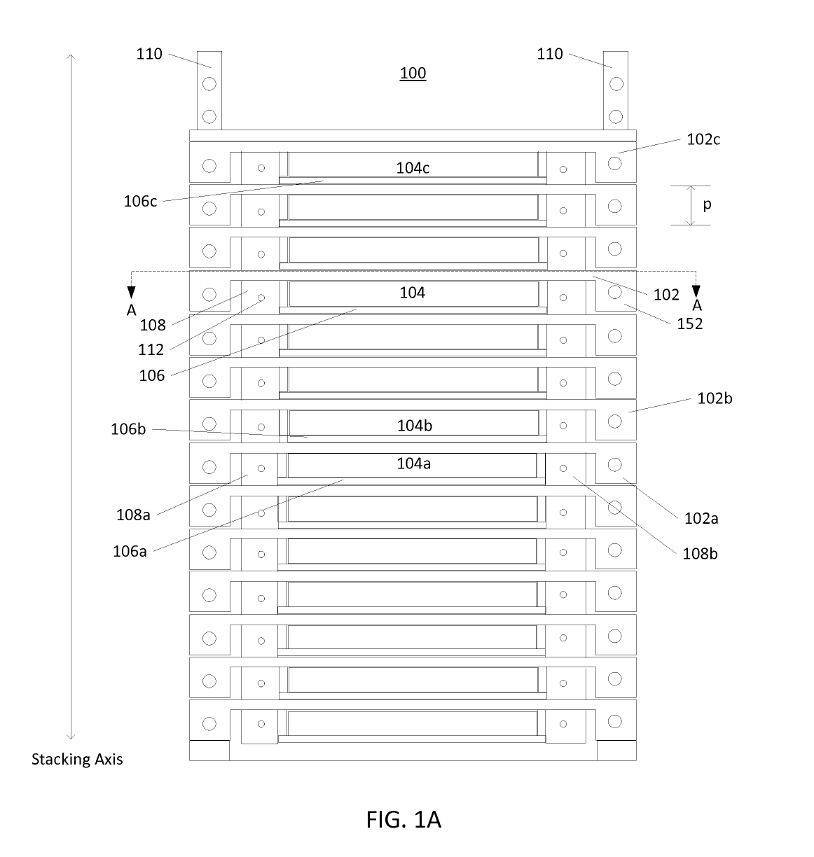

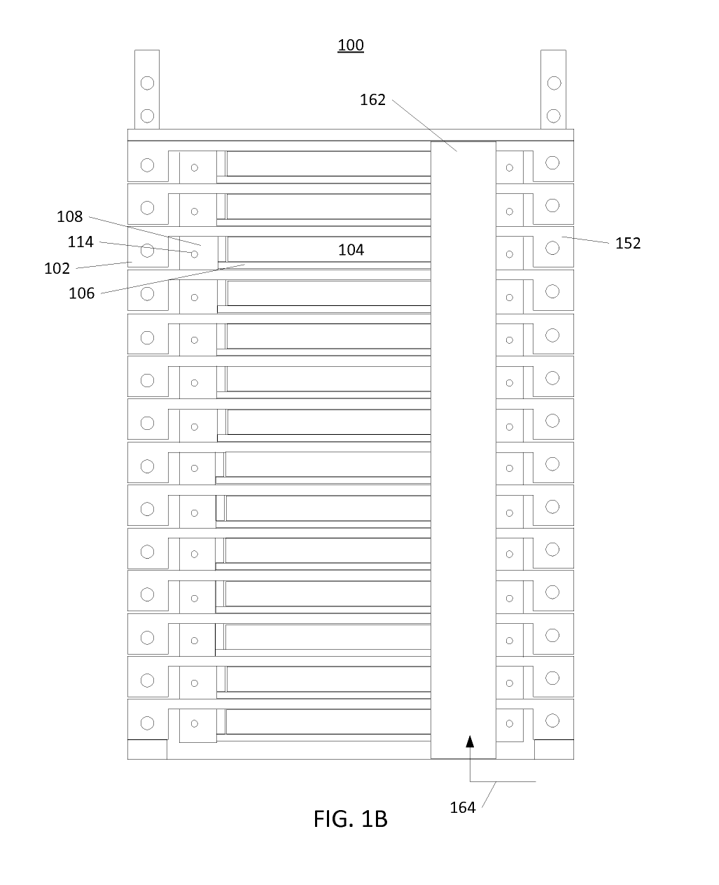

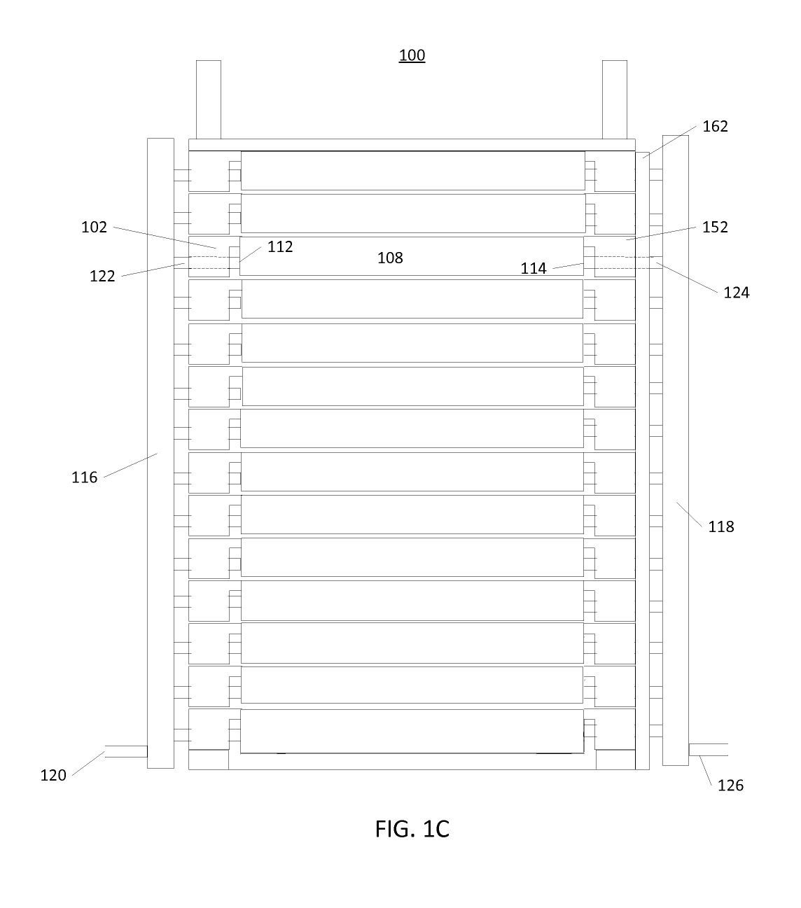

FIGS. 1A, 1B and 1C show a front view, a back view and a side view, respectively, of an example stackable cooling rail based system 100 (or cooling system 100), configured in accordance with some embodiments. Although only a single chassis is shown, in some embodiments cooling system 100 may include multiple interconnected chassis. Cooling system 100 may include a plurality of stackable frames 102, such as stackable frame 102a, stackable frame 102b, and stackable frame 102c shown in FIG. 1A. Although fourteen stackable frames 102 are shown, cooling system 100 may include any number of stackable frames in various embodiments. For example, some embodiments of cooling system 100 may include up to or more than 128 stackable frames.

In some embodiments, one or more of stackable frames 102 may be configured to occupy a fixed distance (referred to herein as the “stacking size”) along the stacking axis when stacked, such that the stacking size may be greater than or equal to a minimum stacking pitch P (e.g., 0.5 inches). Although the stacking size of each of the stackable frames 102 shown in FIG. 1A equals the minimum stacking pitch P shown in FIG. 1A, each of the stackable frames 102 in a chassis may independently have any stacking size that may be greater than or equal to the minimum stacking pitch P, subject only to a constraint of maximum total stacking size aggregated across all of the stackable frames 102 in the chassis, which may be determined by the design of the chassis. In some embodiments, the stacking size of each stackable frame 102 may be one of a discrete set of sizes, e.g., integer multiples or other multiples of the minimum stacking pitch P. In general, combining in a single chassis a set of stackable frames 102 that vary in stacking size, may be advantageous for space efficiency, e.g., when combining in a single chassis components and modules that vary significantly in size along the stacking axis.

Stackable frame 102, like some or all of the other stackable frames, may be configured to receive a module 104, and may include one or more cooling elements 106. Cooling elements 106 may be configured to couple thermally with module 104, to remove heat from a first side (e.g., the bottom) of module 104. In FIGS. 1A, 1B and 1C, stackable frames 102 are stacked together (e.g., tightly together, such being immediately adjacent to one another and/or with minimal to zero intervening space) such that cooling system 100 may be referred to as being in a stacked configuration (e.g., versus the opened configuration). For example and with reference to FIG. 1A, stackable frame 102b may be stacked on top of stackable frame 102a. Stackable frame 102b may also include one or more cooling elements 106b that provide cooling from a first side (e.g., the bottom) to module 104b. Via the stacking, cooling elements 106b may further provide cooling from a second side (e.g., the top) of module 104a of stackable frame 102a. As such, cooling system 100 may provide two-sided cooling to module 104a, as well as to some or all of the other modules 104.

In some embodiments, at least one stackable frame 102 may include one or more cooling rails 108, for example, as shown by cooling rails 108a and 108b of stackable frame 102a. Cooling rails 108 may be made of metal, plastic, and/or any other suitable material, and may in some embodiments be single-phase and/or two-phase fluid heat exchangers. In some embodiments, cooling rails 108 may also be designed to contribute structural load-bearing capacity to the stackable rack-based computing system, in some cases in lieu of other design elements for providing structural load-bearing capacity.

In some embodiments, cooling rails 108 of stackable frame 102 may include cooling rail inlet 112 (e.g., as shown in FIGS. 1A and 1C) and cooling rail outlet 114 (e.g., as shown in FIGS. 1B and 1C) for respectively inputting and outputting a cooling fluid, such as water, a mixture of water with other liquids, refrigerant, and/or other cooling fluids not containing any water (e.g., air, other gases, gaseous/fluid mixtures, etc.). The cooling fluid may flow through cooling rail 108 (e.g., from cooling rail inlet 112 to cooling rail outlet 114) and absorb heat (e.g., dissipated by the module(s)) from thermally coupled cooling elements 106.

As shown in FIG. 1C, cooling system 100 may further include one or more inlet cooling fluid manifolds 116 and one or more outlet cooling fluid manifolds 118 (not shown in FIGS. 1A and 1B, to avoid obscuring other features of cooling system 100). Inlet cooling fluid manifold 116 may receive cooling fluid from an external cooling fluid circuit, such as via manifold inlet 120. Furthermore, inlet cooling fluid manifold 116 may provide cooling fluid to at least one of the one or more cooling rails of the at least one stackable frame, such as via flexible connection 122 as shown in FIG. 1C for cooling rail 108 of stackable frame 102. Outlet cooling fluid manifold 118 may receive cooling fluid from at least one of the one or more cooling rails of the at least one stackable frame, such as via flexible connection 124 for cooling rail 108. Furthermore, outlet cooling fluid manifold 118 may send cooling fluid received from cooling rail 108 to an external cooling fluid circuit, such as via manifold outlet 126. As such, in some embodiments, cooling fluid may be cooled in an external cooling fluid circuit, flow through one or more cooling rails 108 to cool modules 104, and return to the external cooling fluid circuit for cooling, and so forth. In some embodiments, flexible connections 122 and 124 may be flexible hoses, such as tubes made from polymer-based materials, although other suitable materials and shapes may also be used.

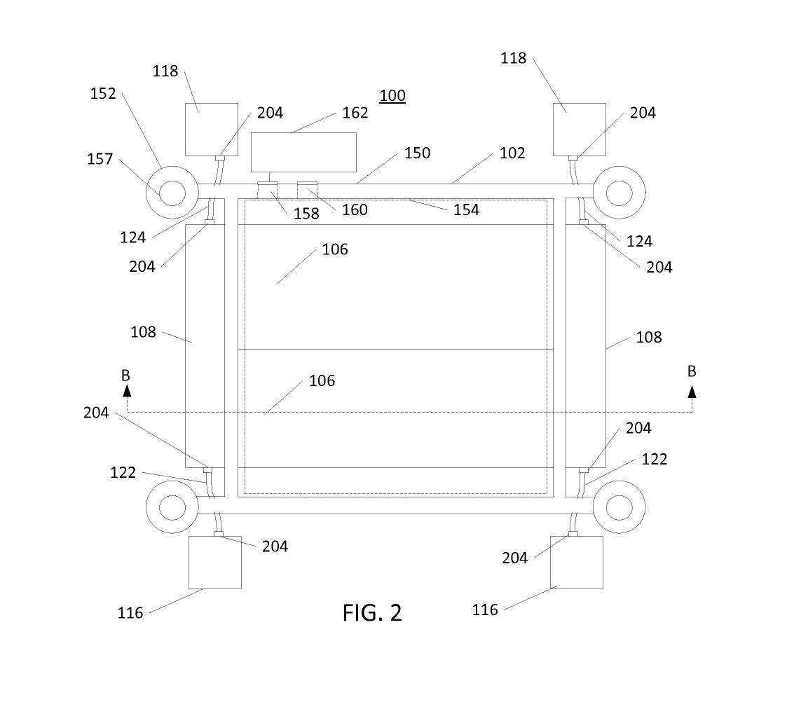

FIG. 2 shows a cross sectional view of cooling system 100 taken along line AA shown in FIG. 1A, in accordance with some embodiments. As shown, cooling system 100 may include two inlet cooling fluid manifolds 116 and two outlet cooling fluid manifolds 118, such as when stackable frame 102 includes two cooling rails 108. In another example, two cooling rails 108 of a single stackable frame 102 may share a single inlet cooling fluid manifold 116 and/or a single outlet cooling fluid manifold 118.

In some embodiments, cooling rails 108, flexible connections 122 and 124, inlet cooling fluid manifolds 116, and/or outlet cooling fluid manifolds 118 may be connected via fittings, such as fittings 204 shown in FIG. 2. Fittings 204 may include one or more mechanical and/or electromechanical elements that collectively are capable of providing removable cooling fluid flow connections while also preventing cooling fluid leakage (e.g., in operation and/or during maintenance). Some example fittings 204 may include hose barbs, threaded nipples, automatic quick-disconnect mechanisms with mating elements that enable fluid flow only when mated, and/or controllable valves. Threaded nipples, for example, may provide for mechanically secure and leakage free connections. When used, quick-disconnect mechanisms and/or controllable valves may be opened to allow cooling fluid flow or closed to provide cooling fluid seals (e.g., during maintenance operations such as removal, addition, and/or replacement of cooling rails 108, flexible connections 122 and 124, inlet cooling fluid manifold 116, outlet cooling fluid manifold 118, stackable frames 102, etc.). This may enable maintenance operations on specific parts of cooling system 100, such as without requiring shutdown and/or other operational disturbances affecting other parts of cooling system 100.

In some embodiments, multiple fittings on each of inlet cooling fluid manifolds 116 and/or outlet cooling fluid manifolds 118, may be disposed substantially parallel to the stacking axis of cooling system 100, and may be spaced at regular intervals that may conform to (e.g., match) the minimum stacking pitch P. In some embodiments, the total number of fittings on each of inlet cooling manifolds 116 and/or outlet cooling manifolds 118, may be sufficient to provide at least one fitting for each of the stackable frames that are installed in cooling system 100, when cooling system 100 is configured with a maximum number of stackable frames (i.e., when the stacking size of each installed stackable frame equals the minimum stacking pitch P, and adding one more stackable frame would exceed a chassis limit on maximum aggregate stacking size). In such embodiments, when fewer stackable frames are installed in cooling system 100 (e.g., when one or more of the stackable frames has a stacking size greater than the minimum stacking pitch P, and/or the total aggregate stacking size is less than a chassis limit), one or more fittings on each of inlet cooling manifolds 116 and/or outlet cooling manifolds 118, may be unused.

In some embodiments, cooling elements 106 of stackable frame 102 may be vapor chambers (or “vapor chambers 106”) and/or similar structures, as shown in FIG. 2. Vapor chambers 106 may be coupled thermally with module 104 (e.g., as shown in FIG. 1A) located at module receiving area 154 (shown in outline in FIG. 2). Although two vapor chambers 106 are shown in FIG. 2, stackable frame 102 may include one or more vapor chambers. For example, the one or more vapor chambers may partially or fully span the area of vapor chambers 106 to provide cooling to module 104 (e.g., as shown in FIG. 1A) located at module receiving area 154 (shown in outline in FIG. 2).

In some embodiments, a first external cooling fluid circuit may be connected with an inlet cooling fluid manifold 116 and outlet cooling fluid manifold 118 that in turn are connected with cooling rails 108 on a first side of vapor chambers 106, while a second independent external cooling fluid circuit may be connected with an inlet cooling fluid manifold 116 and outlet cooling fluid manifold 118 that in turn are connected with cooling rails 108 on a second, opposite side of vapor chambers 106. In this case, if one of these two external cooling fluid circuits fails or is disabled temporarily (e.g., for maintenance), vapor chambers 106 may continue to provide effective cooling, because each of the vapor chambers 106 may continue to reject heat to a still-functioning external cooling fluid circuit, via at least one of its cooling rails 108. In some other embodiments, a single external cooling fluid circuit may be used.

Some embodiments may include additional provisions to help mitigate the risk of a breach along a cooling fluid flow path (e.g., along one or more of inlet cooling fluid manifolds 116, flexible connections 122 and 124, cooling rails 108, and outlet cooling fluid manifolds 118 shown in FIG. 2). For example, one or more additional layers of surrounding material (e.g., multiple-wall construction) may be used along one or more cooling fluid flow paths. Additionally or alternatively, some embodiments may include provisions to help mitigate the risk of damage to components due to exposure to cooling fluid, in the case of a breach along a cooling fluid flow path. For example, one or more mechanical barriers may be included to help isolate module receiving area 154 from any cooling fluid that may escape from one or more of inlet cooling fluid manifolds 116, flexible connections 122 and 124, cooling rails 108, and outlet cooling fluid manifolds 118. As another example, one or more external cooling fluid circuits may be configured such that the pressure of cooling fluid in the cooling fluid flow paths of cooling system 100, is lower than the ambient atmospheric pressure. In the configuration shown in FIG. 1C, cooling fluid may be pulled out of manifold outlet 126 via suction at a pressure that is below atmospheric pressure, instead of being pushed into manifold inlet 120 at a pressure that is above atmospheric pressure. In this case, a breach along a cooling fluid flow path may result in air entrainment that may reduce or stop cooling fluid flow in a cooling fluid circuit, but such a breach may not cause cooling fluid to escape from the cooling fluid circuit.

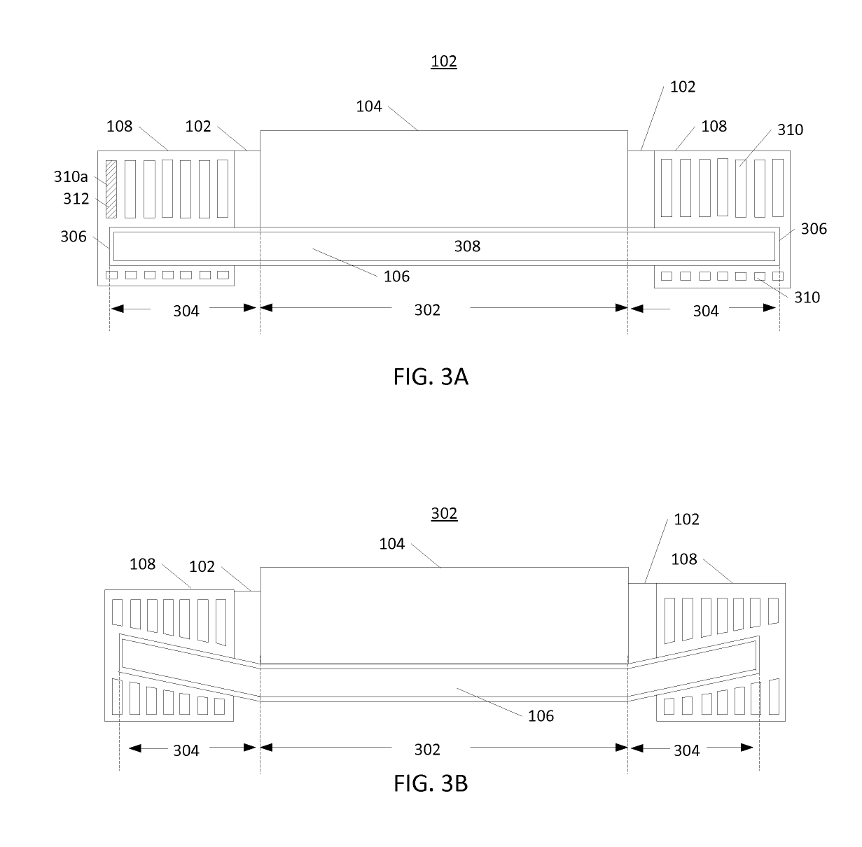

FIG. 3A shows a cross sectional view of stackable frame 102 taken along line BB shown in FIG. 2. Cooling rails 108 and/or vapor chamber 106 may be coupled mechanically with stackable frame 102. Vapor chamber 106 may have a planar structure including a flat, or substantially flat, liquid boiling portion 302 configured to couple thermally with module 104 on a first side (e.g., the top) of vapor chamber 106 and with a second module (not shown) of an adjacent stackable frame on a second side (e.g., the bottom) of vapor chamber 106. Vapor chamber 106 may further include one or more liquid condensing portions 304, at least one of which may be configured to be inserted into slot 306 of cooling rails 108 for thermal coupling with cooling rails 108.

In some embodiments, vapor chamber 106 may include one or more hollow cavities 308 in which liquid, such as water, may be contained. Via heating from the modules, the liquid may boil at liquid boiling portion 302 and evaporate to liquid condensing portions 304. At liquid condensing portions 304, the vaporized liquid may be cooled by cooling rails 108 and condensed back to liquid form. In some embodiments, one or more hollow cavities 308 may include a wick structure to facilitate transport of liquid from liquid condensing portions 304 back to liquid boiling portion 302.

In some embodiments, cooling rails 108 may include one or more fluid channels 310 for cooling fluid flow, such as from cooling rail inlet 112 to cooling rail outlet 114 (e.g., as shown in FIG. 1C). Fluid channels 310 may increase the contact area of cooling fluid and cooling rails 108 to provide enhanced heat transfer. Furthermore, in some embodiments, one or more fluid channels may further include a plurality of smaller channels (e.g., as defined by fins 312) for further increasing contact area, as shown for fluid channel 310a. In some embodiments, heat transfer from vapor chamber or similar structure 106 to cooling rails 108 may be enhanced via various means that may include thermal interface materials and/or permanent attachment via brazing, soldering, and/or other methods. In some other embodiments, cooling rails 108 may be integral parts of vapor chamber or similar structure 106, thereby enhancing heat transfer performance by eliminating thermal interfaces between vapor chamber or similar structure 106, and cooling rails 108.

FIG. 3B shows a cross sectional view of an example stackable frame 302 (e.g., taken along line BB shown in FIG. 2), in accordance with some embodiments. Much of the discussion above of stackable frame 102 in connection with FIG. 3A may be applicable to stackable frame 302, and is not repeated to avoid unnecessarily overcomplicating the disclosure. In some embodiments and as shown in FIG. 3B, vapor chamber 106 may include a non-planar profile, for reasons that may include the use of gravity to help facilitate transport of liquid from liquid condensing portions 304 back to liquid boiling portions 302. For example, vapor chamber 106 may include a U-shaped profile such that liquid boiling portion 302 may be lower (e.g., relative to the ground) than liquid condensing portions 304, such that the vaporized liquid may rise to liquid condensing portions 304, and the condensed liquid may drop with the assistance of gravity to liquid boiling portion 302.

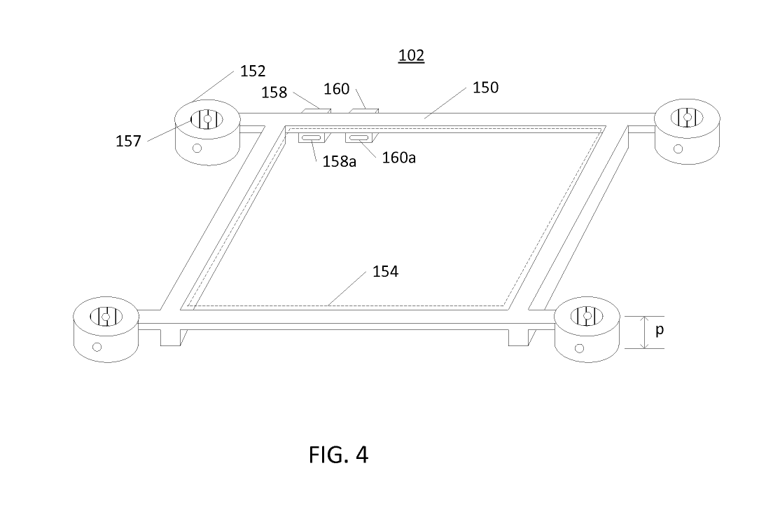

FIG. 4 shows another view of stackable frame 102, in accordance with some embodiments. Stackable frame 102 may include frame 150. Frame 150 may define (e.g., in dimension, shape, design, etc.) a module receiving area 154 (shown in outline) in which a module, such as module 104, may be removably inserted. Once inserted, module 104 may receive cooling at a first surface (e.g., the bottom surface) by cooling element 106, which may also be coupled mechanically with frame 150 (as shown in FIGS. 3A and 3B). In some embodiments, cooling element 106 may further support or otherwise keep the module 104 in place within frame 150.

As shown in FIGS. 2 and 4, stackable frame 102 may include frame spacers 152. One or more of stackable frames 102 may be configured such that along the stacking axis, the stacking size of the stackable frame 102 may be determined by the collective physical extent of frame spacers 152, and the collective physical extent of all of the other parts of the stackable frame 102, including module receiving area 154, cooling element 106, and cooling rails 108, may fit entirely within the collective physical extent of frame spacers 152.

In some embodiments, one or more of the outer surfaces of module 104 and/or cooling element 106 may include one or more layers of Thermal Interface Material (TIM), such as conformable and/or compressible thermally-conductive foams, sponges, pads, putties, gap-fillers, shims, and/or other suitable forms of thermal interface materials. This TIM may help improve the efficiency of waste-heat transfer from module 104 to adjacent cooling elements 106. If present, this TIM may cause the collective physical extent along the stacking axis of a module 104 and adjacent cooling elements 106, to exceed the collective physical extent along the stacking axis of frame spacers 152 of a stackable frame 102, when cooling system 100 is in an opened configuration and/or the TIM is in an uncompressed state. The TIM may be designed to compress such that when cooling system 100 is in a stacked configuration, the TIM provides enhanced heat-transfer capability, and the collective physical extent along the stacking axis of module 104 (including TIM) and adjacent cooling elements 106, conforms to (e.g., matches) the collective physical extent along the stacking axis of frame spacers 152 of stackable frame 102.

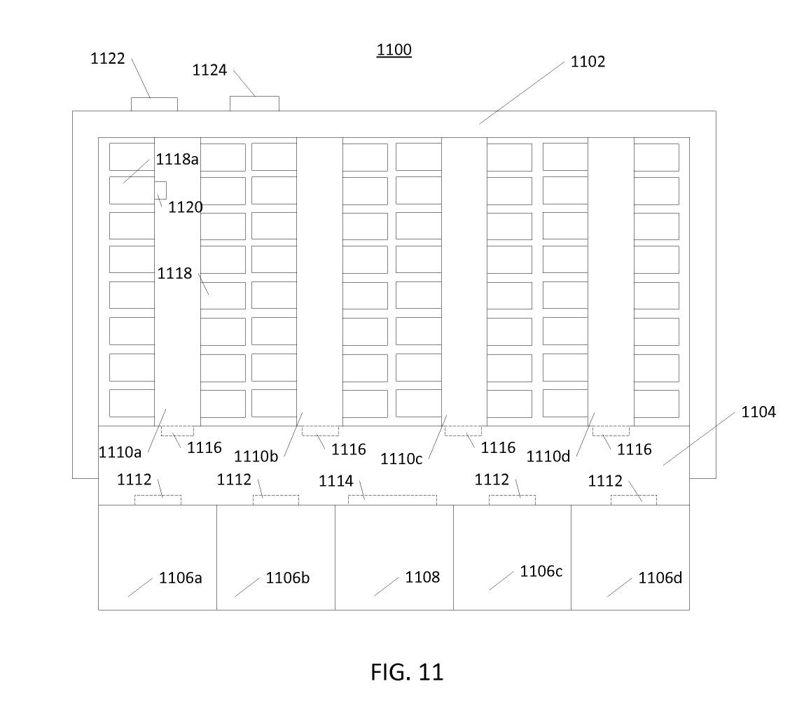

In some embodiments, stackable frame 102 may further include power connector 158 and network connector 160 for respectively providing power and data networking to module 104, as shown in FIGS. 2 and 4. Power connector 158 may include a first interface that receives power via a flexible cable connection from power distribution unit 162 (e.g., as shown in FIGS. 1B, 1C and 2) and a second interface (e.g., shown at 158a in FIG. 4) that transmits the received power to module 104 (e.g., via a module power connector of module 104, an example of which is shown in FIG. 11 as module power connector 1122). Power distribution unit 162 may receive power from an external source and convert the power to a format suitable for power connector 158. For example, power distribution unit 162 may convert a received three-phase 480 Vrms AC power source into a single-phase 277 Vrms AC power source for at least one module. One of the single-phase 277 Vrms AC power sources may be sent to power connector 158. In other embodiments, power distribution unit 162 may be configured to provide a DC power source, for example at a fixed voltage within an approximate range of 12 to 400 V DC, for the at least one module. As shown in the back view of cooling system 100 in FIG. 1B, power distribution module 162 may be disposed along the stacking axis of cooling system 100. Power distribution module 162 may receive external power at 164 (e.g., the three-phase 480 Vrms AC power source), perform suitable conversions, and distribute the power to modules 104.

Referring to FIGS. 1B and 2, in some embodiments the flexible cable connection between power distribution unit 162 and power connector 158 may be attached to power distribution unit 162 via an outlet that may be configured for a hardwired, plug/socket, or other type of attachment. In some embodiments, multiple outlets on power distribution unit 162 may be disposed substantially parallel to the stacking axis of cooling system 100, and may be spaced at regular intervals that may conform to (e.g., match) the minimum stacking pitch P. In some embodiments, the total number of outlets on power distribution unit 162 may be sufficient to provide at least one outlet for each of the stackable frames that are installed in cooling system 100, when cooling system 100 is configured with a maximum number of stackable frames (i.e., when the stacking size of each installed stackable frame equals the minimum stacking pitch P, and adding one more stackable frame would exceed a chassis limit on maximum aggregate stacking size). In such embodiments, when fewer stackable frames are installed in cooling system 100 (e.g., when one or more of the stackable frames has a stacking size greater than the minimum stacking pitch P, and/or the total aggregate stacking size is less than a chassis limit), one or more outlets on power distribution unit 162 may be unused.

Although power distribution unit 162 is shown in FIG. 2 as immediately adjacent to power connector 158, the flexible cable connection between power distribution unit 162 and power connector 158 may be of any length, so power distribution unit 162 may be placed in any (e.g., convenient, space efficient, etc.) location relative to the other elements of cooling system 100.

Returning to FIGS. 2 and 4, network connector 160 may be configured to provide network connectivity for module 104, such as with one or more other modules within the same chassis, one or more modules in other chassis, and/or one or more devices that are not part of the stackable cooling rail based system. In some embodiments, network connector 160 may include a first interface in communication with a network module configured to perform network interconnection, and a second interface (e.g., shown at 160a in FIG. 4) in communication with module 104 (e.g., via a module network connector of module 104, an example of which is shown in FIG. 11 as module network connector 1124). In various embodiments, cooling system 100 and its networking elements (e.g., network connector 160) may use one or more data cables for data connections. Each such cable may include one or more data links. Each such link may be unidirectional and/or bidirectional, and may employ any suitable combination of one or more signaling technologies, including but not limited to electrical signaling and optical signaling. In one example, at least one network connector 160 may interface with a cable that may include up to 32 unidirectional input links and up to 32 unidirectional output links.

Frame 150 may also include a plurality of frame spacers 152. A frame spacer 152 may include a chassis pole hole 157 such that frame spacer 152 may receive chassis pole 110 (e.g., as shown in FIG. 1A) through chassis pole hole 157. In some embodiments, cooling system 100 may include four chassis poles 110, and at least one of the stackable frames 102 may include four frame spacers 152. However, the number of chassis poles and frame spacers per stackable frame may be different in other embodiments. Chassis poles 110 may be disposed substantially parallel to each other to provide a skeletal structure (e.g., of four chassis poles 110) for aligning the stackable frames 102 within cooling system 100. In some embodiments, chassis poles 110 may define the stacking axis. Once stacked within the skeletal structure, at least one stackable frame 102 may be movable along the stacking axis, as shown in FIG. 1A.

In some embodiments, stackable frames 102 may be stacked via their frame spacers 152, as shown in FIGS. 1A, 1B and 1C. Advantageously, frame spacers 152 may support most or all of the weight of stackable frame 102 (e.g., as opposed to the more delicate modules 104, cooling elements 106, and/or cooling rails 108). Frame spacers 152 may also support most or all of the weight of all of the stackable frames that may be stacked on top of stackable frame 102. In some embodiments, one or more of the outer surfaces of a module and/or the cooling elements of a stackable frame, may include conformable and/or compressible TIM, such that when the module is inserted in the stackable frame and the stackable cooling rail based system is in a stacked configuration with all of the frame spacers on at least one chassis pole stacked together, the frame spacers may ensure that a precisely calibrated force is applied to compress the TIM for enhanced heat-transfer performance.

In some embodiments, at least one of modules 104 within cooling system 100 may be a network module. For example, module 104c shown in FIG. 1A, which receives only single sided cooling from cooling element 106c, may be a network module (e.g., in embodiments where a network module requires less cooling than other modules require).

A network module may provide one or more “internal” network ports. An internal port of a network module may be connected with a module 104 such that modules 104 that are connected with the network module may communicate with each other. The network module may also provide one or more “external” network ports. An external port of a network module may be connected with an external port of another network module, or with a network port of a device that is not part of the stackable cooling rail based system.

Interconnecting a plurality of network modules, via their external ports, may create a scalable network that may span one or more chassis. Such a network may provide connectivity among modules 104 that are connected with the internal ports of the plurality of interconnected network modules. This scalable network may also be interconnected with one or more networks that are not part of the stackable cooling rail based system, via connections with one or more external ports of the plurality of interconnected network modules.

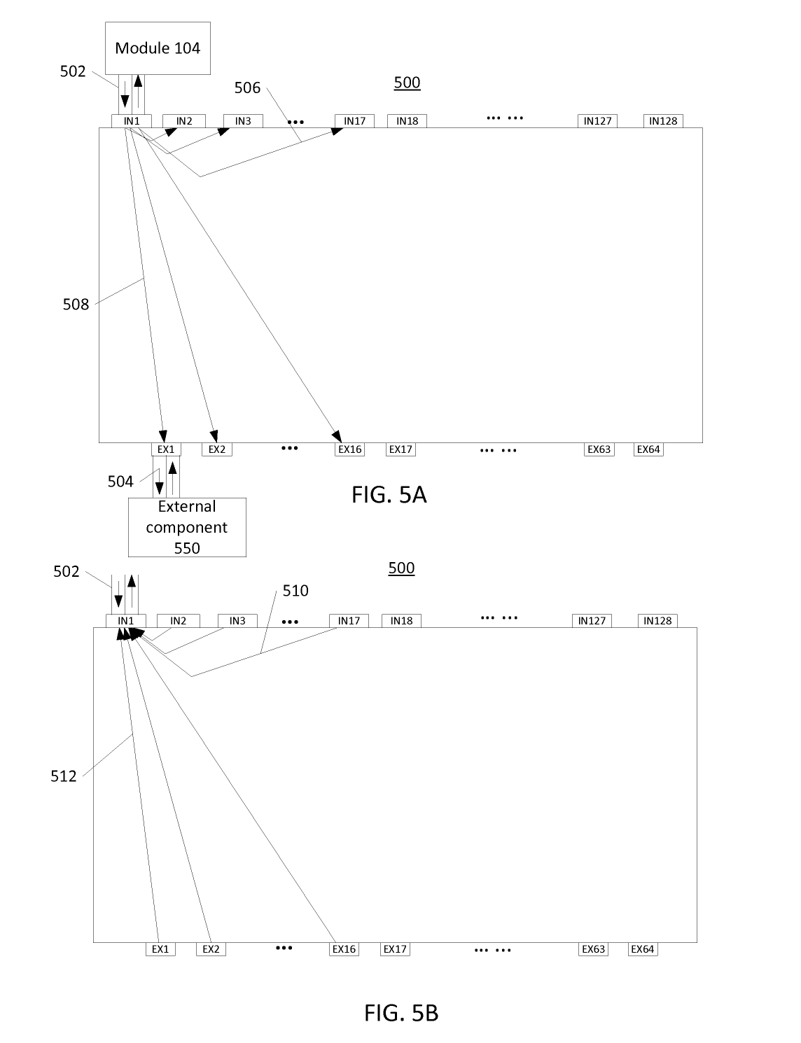

FIGS. 5A and 5B show connections within an example network module 500, configured in accordance with some embodiments. Network module 500 is shown as being configured for up to 128 internal ports and up to 64 external ports. For example, network module 500 may include 128 internal network ports IN1-IN128 configured to connect with modules 104 via network connectors 160 of stackable frames 102. Network module 500 may further include 64 external network ports EX1-EX64 configured to interface with external components such as external component 550, which may be an external port of another network module, or a device that is not part of the stackable cooling rail based system. In some embodiments, network ports of a network module may be configured to interface with data cables. FIG. 5A shows data cables 502 and 504 that may each include up to 32 unidirectional input links and up to 32 unidirectional output links.

In some embodiments, a network module may be configured for passive interconnection, where modules 104 may be interconnected with each other and/or with one or more of the external network ports of the network module. FIG. 5A shows example output connections 506 and 508 within network module 500 configured to transfer data from a module 104 connected with internal network port IN1. As shown, 16 output connections 506 (e.g., from a first 16 of the 32 output links of cable 502) may connect internal network port IN1 to internal network ports IN2-IN17. Furthermore, 16 output connections 508 (e.g., from a second 16 of the 32 output links of cable 502) may further connect internal network port IN1 with external network ports EX1-EX16. In other embodiments, not depicted in FIG. 5A, each of the 32 output links of cable 502 may be connected with any of the ports IN2-IN128 and EX1-EX64, as necessary to produce a specific fixed interconnection topology. Similarly, each of the ports IN2-IN128 may also receive a cable 502 connected with a module 104, with each of the cable's 32 output links connected, within network module 500, with any of the other internal and/or external network ports.

FIG. 5B shows example input connections 510 and 512 of network module 500 configured to transfer data to a module 104 connected with internal network port IN1. As shown, 16 input connections 510 (e.g., routed to a first 16 of the 32 input links of cable 502) may connect internal network ports IN2-IN17 with internal network port IN1. Furthermore, 16 input connections 512 (e.g., routed to a second 16 of the 32 input links of cable 502) may further connect external network ports EX1-EX16 with internal network port IN1. In other embodiments, not depicted in FIG. 5B, each of the 32 input links of cable 502 may be connected with any of the ports IN2-IN128 and EX1-EX64, as necessary to produce a specific fixed interconnection topology. Similarly, each of the ports IN2-IN128 may also receive a cable 502 connected with a module 104, with each of the cable's 32 input links connected, within network module 500, with any of the other internal and/or external network ports.

In some embodiments, a network module may be configured to perform active switching/routing. For example, network module 500 may include a set of internal elements that may collectively be configured to programmatically switch/route data among the internal network ports IN1-IN128 and external network ports EX1-EX64.

In some embodiments, a set of one or more network modules, each internally employing passive interconnection and/or active switching/routing, and spanning one or more chassis, may be interconnected via one or more cables attached to their external network ports. The topology of the resulting scalable network may be a multidimensional torus, hypercube, butterfly, or any other suitable topology.

In some embodiments, one or more “port fillers” may be attached to one or more ports on network module 500 that are unused (e.g., not connected with a cable) in a specific configuration of cooling system 100. Each such port filler may provide one or more passive and/or active interconnections among the input and output links of one or more otherwise-unconnected ports, and thereby may create additional usable paths within a scalable network created by one or more interconnected network modules 500.

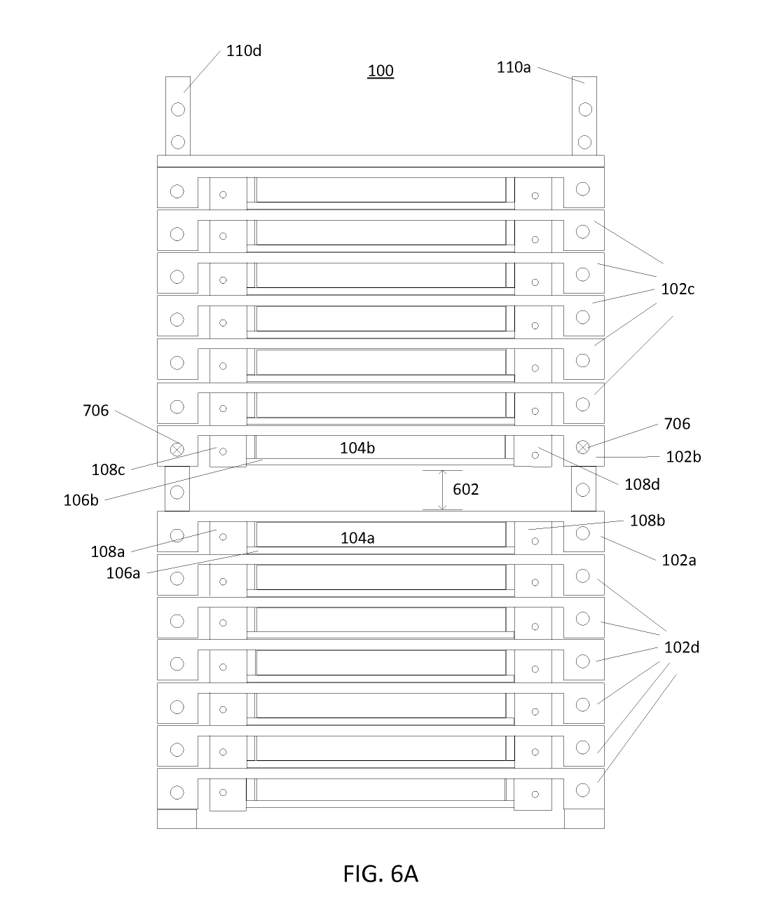

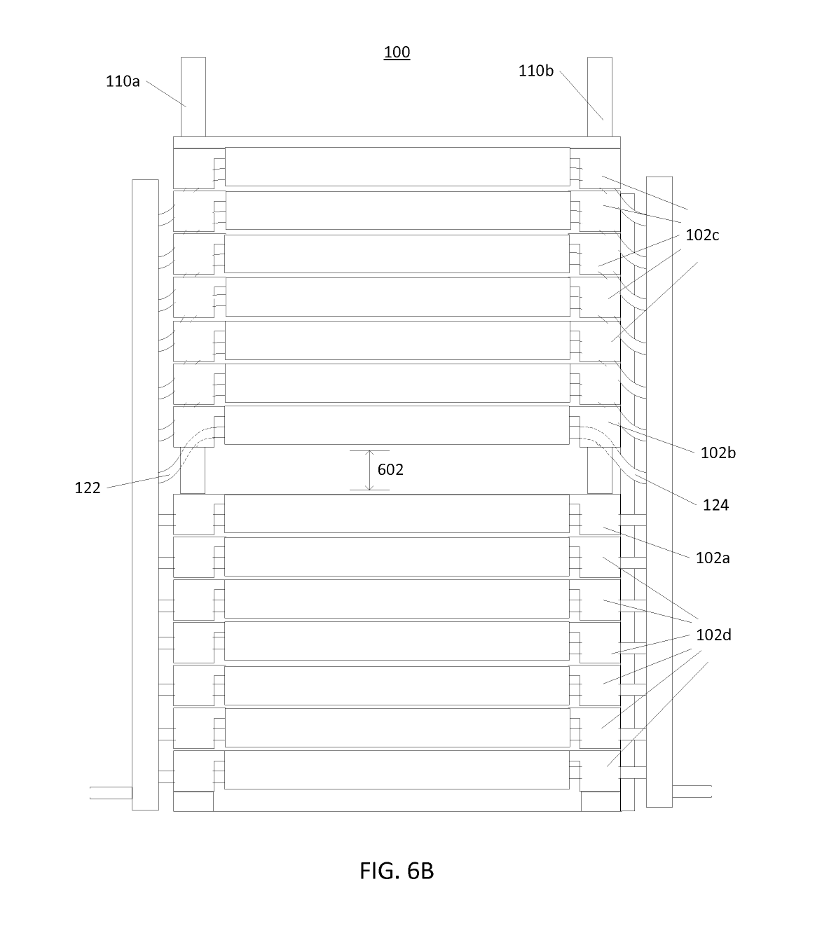

FIGS. 6A and 6B show a front view and a side view, respectively, of example cooling system 100 in an opened configuration, in accordance with some embodiments. Cooling system 100 may be configured to transform between the opened configuration and the stacked configuration. As discussed above, the opened configuration refers to a configuration of cooling system 100 where at least one pair of consecutively stacked stackable frames 102, including the one or more cooling rails 108 of each of the pair of consecutively stacked stackable frames 102, are separated by an access gap. The access gap may be used to provide access to the modules 104, stackable frames 102, cooling elements 106, cooling rails 108, components of the module, etc. for purposes such as installation, repair, replacement, removal, configuration, reconfiguration, troubleshooting, upgrades, or the like.

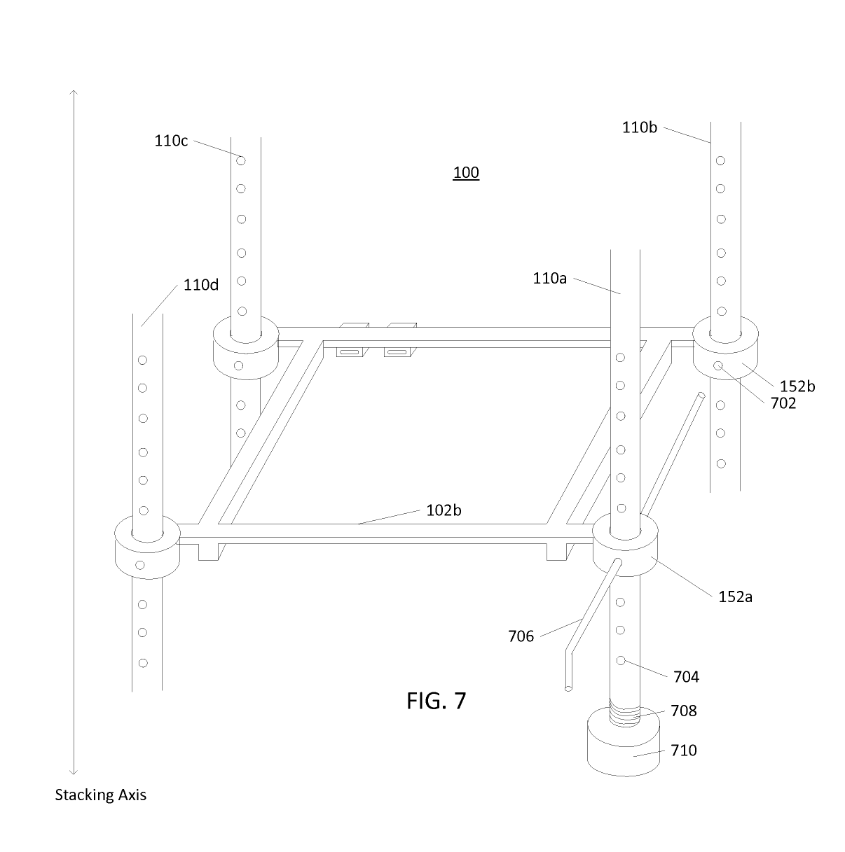

As shown in FIGS. 6A and 6B, access gap 602 may be opened between stackable frames 102a and 102b to provide access to stackable frames 102a and 102b, modules 104a and 104b (shown in FIG. 6A), cooling elements 106a and 106b (shown in FIG. 6A), cooling rails 108a, 108b, 108c and 108d, etc. Similar access gaps 602 may be opened between any other pairs of consecutively stacked stackable frames. FIG. 7 shows a simplified view of cooling system 100 that includes stackable frame 102b and chassis poles 110a, 110b, 110c and 110d, in accordance with some embodiments. As shown, each frame spacer (e.g., frame spacers 152a and 152b) of stackable frame 102b may include frame pin holes 702. Furthermore, each chassis pole 110a-110d may include pole pin holes 704, such as at least one pole pin hole 704 for each stackable frame of cooling system 100 (e.g., 128 pole pin holes 704, or more, for each chassis pole to support 128 stackable frames). In some embodiments, the distance between any two adjacent pole pin holes 704 of a chassis pole 110 may also be configured to conform to the minimum stacking pitch P. For example, each pole pin hole may be separated from an immediately adjacent pole pin hole by exactly the minimum stacking pitch P. Frame pin holes 702 and pole pin holes 704 may be configured to receive pin 706. Once received, pin 706 may mechanically couple (e.g., lock or otherwise attach mechanically) stackable frame 102b with a chassis pole, such as chassis pole 110a. In some embodiments, a pin may be threaded through more than one group of frame pin holes 702 and pole pin holes 704, to couple a stackable frame with more than one chassis pole. For example, stackable frame 102b may be coupled with chassis pole 110a and chassis pole 110b via pin 706. Similarly, stackable frame 102b may be coupled with chassis poles 110c and 110d via one or more pins.

After stackable frame 102b has been coupled mechanically with chassis poles 110a-110d, chassis poles 110a-110d may be moved (e.g., mechanically) along the stacking axis, thereby causing stackable frame 102b to move in unison with the motion of chassis poles 110a-110d. For example, chassis poles 110a-110d may be raised to create access gap 602 between stackable frame 102b and stackable frame 102a in the opened configuration, as shown in FIGS. 6A and 6B. Stackable frames 102c, above stackable frame 102b, may not be coupled with chassis poles 110a-110d via pins. Instead, stackable frames 102c may rest on stackable frame 102b (e.g., via their frame spacers), and accordingly may move in unison with the motion of chassis poles 110a-110d and stackable frame 102b. Stackable frame 102a, as well as stackable frames 102d below stackable frame 102a, may also not be coupled with chassis poles 110a-110d. As such, chassis poles 110a-110d may slide freely through the chassis pole holes of the frame spacers of stackable frames 102a and 102d, and accordingly movement of chassis poles 110a-110d may not cause movement of, or affect the location of, stackable frames 102a and 102d. Similarly, chassis poles 110a-110d may subsequently be lowered (e.g., from the opened configuration) such that access gap 602 no longer exists between stackable frame 102b and stackable frame 102a in the stacked configuration.

In some embodiments, chassis poles 110a-110d may be configured to move in unison along the stacking axis, via any suitable mechanical means. Chassis pole 110a shown in FIG. 7 (as well as the other chassis poles), for example, may include a threading 708 and a rotatable bolt 710. Via controlled rotation of rotatable bolt 710, threading 708 of chassis pole 110a may cause chassis pole 110a to move (e.g., up or down) along the stacking axis. In various embodiments, uniform control of the rotatable bolts may be performed by mechanical means (e.g., one or more manually operated mechanisms), electromechanical means (e.g., a motor configured to generate forces that rotate the rotatable bolts), and/or computer-controlled electromechanical means (e.g., a processor executing a software program for controlling the motor).

The use of pins as described herein is only one example of suitable means for opening and closing an access gap between a pair of consecutively stacked stackable frames. For example, some embodiments may utilize one or more wedges that may be removably inserted between frame spacers. In another example, an external service device (e.g., a specialized forklift-type unit, robotic apparatus, and/or any other type of mechanism that is external to, and separate from, cooling system 100) may also be used. In some embodiments, cooling system 100 may include bifurcated groups of stackable frames. For example, a first group of stackable frames (e.g., at the top of the stack) may be configured to shift (e.g., upward) in the opened configuration such that an access gap may be opened between any pair of consecutively stacked stackable frames in the first group of stackable frames. A second group of stackable frames (e.g., at the bottom of the stack) may be configured to shift (e.g., downward) in the opened configuration such that an access gap may be opened between any pair of consecutively stacked stackable frames in the second group of stackable frames. Advantageously, such bifurcation may enable concurrent opening of multiple access gaps within cooling system 100.

In some embodiments, two or more stackable frames may be integrated to form a single combined stackable frame. For example and with reference to FIG. 1A, stackable frames 102a and 102b may form a single combined stackable frame. Additionally and/or alternatively, left cooling rail 108a of stackable frame 102a may be integrated with the left cooling rail of stackable frame 102b to form a single combined cooling rail, and likewise for right cooling rail 108b of stackable frame 102a and the right cooling rail of stackable frame 102b. Here, for example, access to module 104a may be attained by lifting stackable frame 102a, and access to module 104b may be attained by lifting the stackable frames above stackable frame 102b.

In some embodiments, flexible connections 122 and 124 may be configured to flex or otherwise adapt mechanically to support adjustability between the opened and stacked configuration, as shown in FIG. 6B. The extent of the flexing of flexible connections 122 and 124 in FIG. 6B is exaggerated because of the exaggerated stacking size of stackable frames 102 depicted in FIG. 6B, as well as for explanatory clarity.

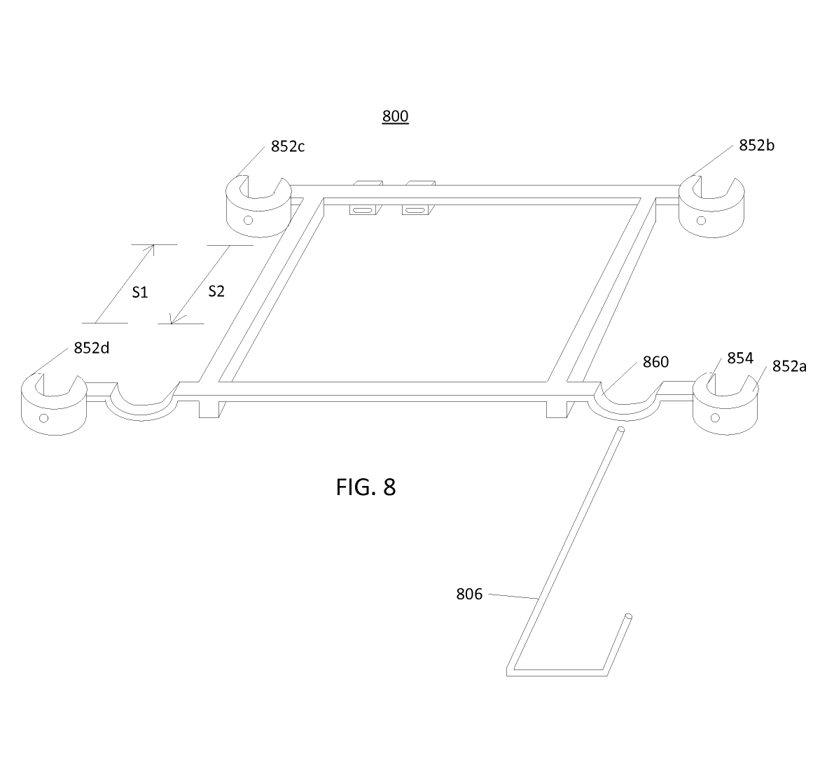

In some embodiments, a stackable cooling rail based system may be configured for efficient addition and/or removal of any stackable frame to/from the stackable cooling rail based system. FIG. 8 shows an example stackable frame 800, in accordance with some embodiments. Stackable frame 800 may be similar to stackable frames 102 in many respects that are not repeated to avoid unnecessarily overcomplicating the disclosure. Stackable frame 800 may include U-shaped frame spacers 852, as shown by U-shaped frame spacers 852a, 852b, 852c, and 852d. U-shaped spacers 852 may be shaped such that stackable frame 800 can be moved along direction S1 (and/or lifted) to interface with chassis poles (e.g., as shown in FIG. 7, except spaced in accordance with the U-shaped frame spacers 852) such that the chassis poles are within chassis pole U-holes 854. When the chassis poles are within the chassis pole U-holes 854 of each of the U-shaped spacers 852, the stackable frame 800 may be considered added to the stackable cooling rail based system. Similarly, stackable frame 800 may be moved in direction S2 (and/or lifted) away from the chassis poles and removed from the stackable cooling rail based system.

In some embodiments, stackable frame 800 may be configured to receive a pin 806 to couple mechanically with chassis poles for movement. As shown, pin 806 may be shaped to support the location of U-shaped spacers 852a and 852b. Furthermore, frame arm 860 may be curved to receive and/or guide pin 806 toward the frame pin hole of U-shaped spacer 852b.

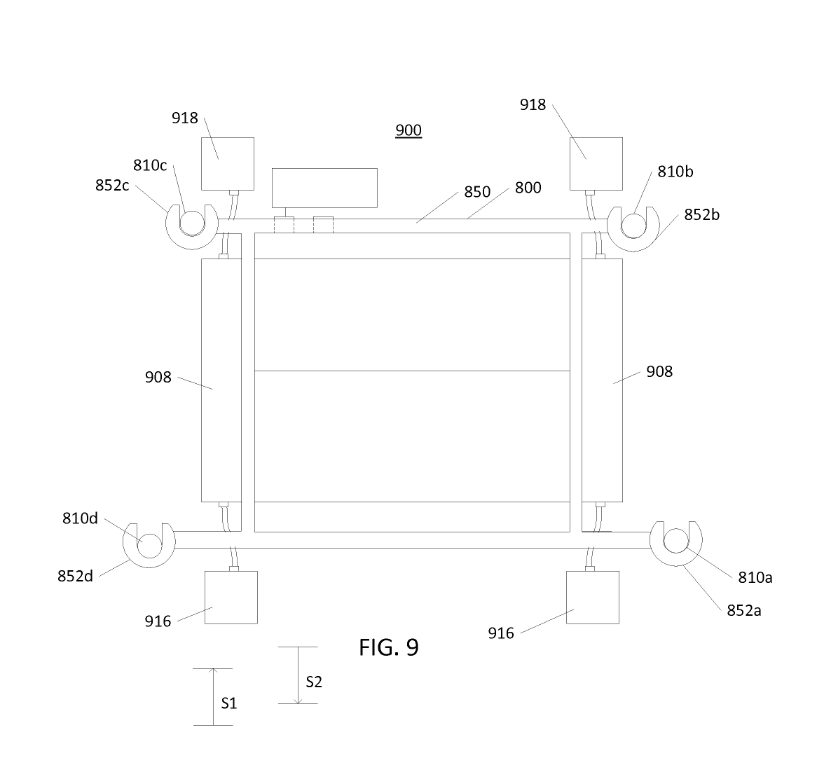

FIG. 9 shows a cross sectional top view of an example stackable cooling rail based system 900 (or cooling system 900), configured in accordance with some embodiments. Cooling system 900 may use techniques for transitioning between a stacked configuration and an opened configuration that are similar to those discussed above for cooling system 100, such as frame pin holes, pole pin holes, and movable pins that can be used to mechanically couple stackable frames 800 with chassis poles 810. Furthermore, when an access gap is present between a pair of consecutively stacked stackable frames 800 (e.g., in the opened configuration), one or more of the stackable frames 800 may be readily added and/or removed. For example, stackable frame 800 shown in FIG. 8 may be selected for removal from cooling system 900. First, inlet cooling fluid manifolds 916 and outlet cooling fluid manifolds 918 may be uncoupled from stackable frame 800 and cooling rails 908. Next, stackable frame 800 may be moved along direction S2 for removal. After stackable frame 800 is removed, the next stackable frame may then be removed in a similar manner, and so forth for each stackable frame below stackable frame 800. Similarly, a stackable frame may be added on top of stackable frame 800 (e.g., via movement along direction S1), the cooling rails may be coupled with inlet cooling fluid manifolds 916 and outlet cooling fluid manifolds 918, and another stackable frame may be added thereafter, and so forth (e.g., depending on the size of the access gap that is opened, and the capacity of cooling system 900 in terms of power, cooling, networking, chassis pole length, etc.).

In some embodiments, U-shaped spacers 852a-852d and chassis poles 810a-810d may be positioned such that stackable frame 800 may be removed from and/or added to cooling system 900 without, for example, U-shaped spacers 852b and 852c being impeded by chassis poles 810a and 810d, respectively. Accordingly, the positions of U-shaped spacers 852 and chassis poles 810, as shown in FIG. 9, may differ from the positions of the corresponding features of cooling system 100 that are shown in FIG. 2. For example, U-shaped spacers 852b and 852c may be positioned closer to the center of frame 850, U-shaped spacers 852a and 852d may be positioned farther from the center of frame 850, and chassis poles 810a-810d may be disposed accordingly.

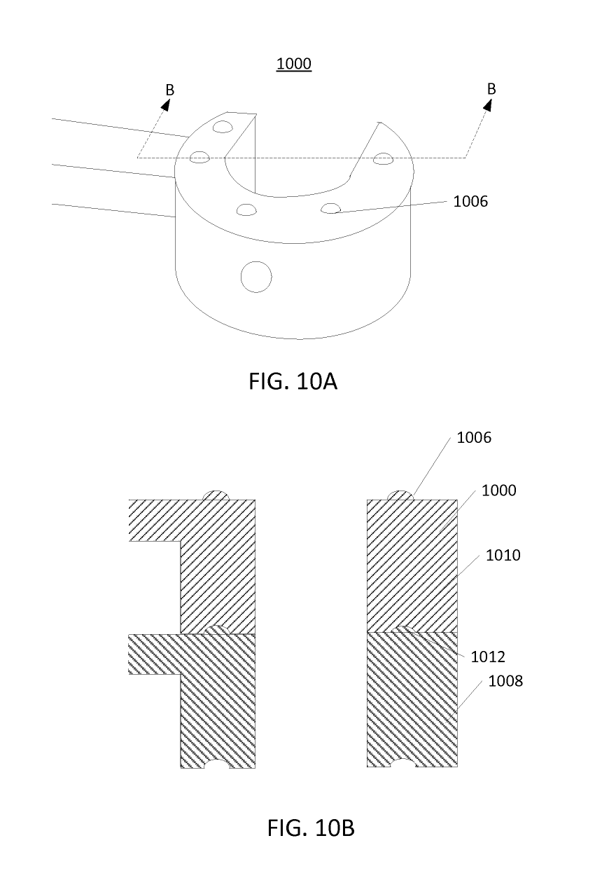

In some embodiments, one or more of U-shaped spacers 852a-852d may include anti-sliding elements to prevent undesirable sliding of stackable frame 800 in the stacked configuration. Sliding may occur, for example, along the direction S2 shown in FIG. 9, because of the opened sides of the U-shaped spacers 852a-852d. FIG. 10A shows a magnified view of an example U-shaped spacer 1000, in accordance with some embodiments. U-shaped spacer 1000 may include one or more raised structures, or “balls,” as used herein, on a first surface. On a second surface opposite to the first surface, U-shaped spacer 1000 may include one or more correspondingly shaped indentations, or “detents,” as used herein. The balls and detents may include corresponding structures, such as hemispheres, that allow the balls and detents of consecutively stacked stackable frames to interlock and thereby hold the stackable frames in place. FIG. 10B shows a cross sectional view of U-shaped spacer 1000 along line BB shown in FIG. 10A, where U-shaped spacer 1000 is stacked on top of U-shaped spacer 1008. As shown, detent 1010 of U-shaped spacer 1000 may interlock with ball 1012 of U-shaped spacer 1008, to keep U-shaped spacer 1000 more firmly secured on top of U-shaped spacer 1008. In various embodiments, any other type of suitable anti-sliding elements may be used. For example, the U-shaped spacers may be held in place by magnetic elements, such as where each U-shaped spacer may include positive and negative magnetic poles that attract opposing poles on consecutively stacked U-shaped spacers.

FIG. 11 shows a top view of an example marina brain board assembly 1100, in accordance with some embodiments. Marina brain board assembly 1100 is an example of a module that may be placed within a stackable frame to receive two-sided cooling, such as module 104 shown in FIG. 1A. Other types of module may include any configuration of components (e.g., in terms of number, placement, and/or function of the components) and receive similar two-sided cooling, power, networking, scalability and serviceability, as discussed above in connection with various embodiments of cooling rail based systems. In various embodiments, components in a module may incorporate any number of different types of processes and/or functions, including but not limited to electrical, mechanical, electromechanical, electronic, optical, thermal, chemical, biological, quantum-physical, and/or nuclear processes and/or functions.

Of various compatible configurations, marina brain board assembly 1100 may provide enhanced serviceability by separating different potential points of failure into removably interconnected pieces. Marina brain board assembly 1100 may include a module frame 1102 to which the various components, such as boardwalk board 1104 and/or pier boards 1110a-1110d, may be mounted. Boardwalk board 1104 may be configured to provide a functional and mechanical (e.g., attachment) interface for power boards 1106a-1106d, network switch/router board 1108, and pier boards 1110a-1110d. For example, boardwalk board 1104 may include power connectors 1112 to receive power from power boards 1106a-1106d. In some embodiments, power connectors 1112 may be configured to be connectable with any of power boards 1106a-1106d and/or replacements thereof. Boardwalk board 1104 may further include network connector 1114 configured to exchange data with network switch/router board 1108.

Boardwalk board 1104 may further include pier connectors 1116 configured to provide power and networking (e.g., as relayed from one or more power boards 1106 and network switch/router board 1108, respectively) to pier boards 1110a-1110d. In some embodiments, pier connectors 1116 may be configured to be connectable with any of pier boards 1110a-1110d and/or replacements thereof.

Each pier board 1110a-1110d may be configured to provide a functional and mechanical (e.g., attachment) interface for boat lobe boards 1118, such as with eight boat lobe boards 1118 on each side of a pier board 1110. For example, pier board 1110a may include a boat connector 1120 configured to removably connect with boat lobe board 1118a, other boat lobe boards 1118, and/or replacements thereof. In some embodiments, each of pier boards 1110a-1110d may include sixteen boat connectors 1120, to connect with sixteen boat lobe boards 1118. Furthermore, each of the sixteen boat connectors 1120 may provide power and networking (e.g., as relayed from one or more power boards 1106 and network switch/router board 1108, respectively, via boardwalk board 1104) to a boat lobe board 1118.

In some embodiments, boardwalk board 1104 and/or pier boards 1110a-1110d may be coupled mechanically with module frame 1102, while power boards 1106a-1106d, network switch/router board 1108, and/or boat lobe boards 1118 may be coupled mechanically with marina brain board assembly 1100 only via boardwalk board 1104 or pier boards 1110a-1110d. As such, a failure in any of the individual power, networking, or processing components may be remedied efficiently by replacing a board. Relative to other known architectures that integrate a larger number of components onto each board, the marina brain board architecture described herein reduces waste of properly functioning components when a board containing a failed component is replaced. For example, a failed boat lobe board 1118 may be removed via the connectors, and a replacement boat lobe board 1118 may be attached, without affecting other, properly functioning boat lobe boards 1118.

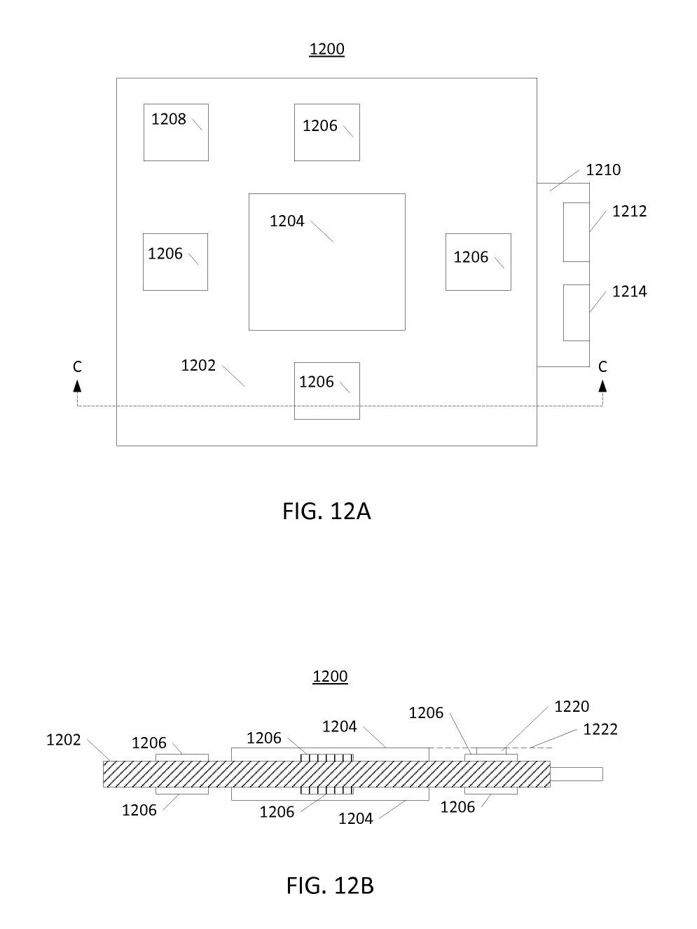

FIG. 12A shows a top view of an example boat lobe board 1200, and FIG. 12B shows a cross sectional view of boat lobe board 1200 taken along line CC in FIG. 12A, configured in accordance with some embodiments. Boat lobe board 1200 may include printed circuit board (PCB) 1202, which may include components disposed on each of two sides, as shown in FIG. 12B. Some example components may include processing component 1204, memory/storage components 1206, and boat power converter component 1208. Components may be mounted to PCB 1202 singly and/or 3D-stacked, via Through-Silicon Via (TSV) and/or other stacking techniques.

Boat lobe board 1200 may include on each of two sides of PCB 1202 a processing component 1204, memory/storage components 1206, and a power converter component 1208. Boat lobe board 1200 may further include a pier connector 1210 configured to removably connect with a boat connector 1120 of a pier board 1110 as shown in FIG. 11, to provide power and networking to boat lobe board 1200. Accordingly, pier connector 1210 may include a network connector 1212 and a power connector 1214.

In some embodiments, the components on a first side of PCB 1202 may form a self-contained set of data-machine resources, referred to herein as a “node”, and the components on a second side of PCB 1202 may form a separate node that operates completely independently from, and does not communicate directly with, the node on the first side of PCB 1202. With respect to FIG. 12A, processing component 1204 may include processing circuitry that, for example, may execute instructions stored in memory/storage components 1206 to perform various computing functions. For example, processing component 1204 may be a SoC unit. Furthermore, processing component 1204 may include integrated networking interface(s) connected with network connector 1212 (e.g., via PCB 1202). Alternatively, one or more networking interface components may be included on boat lobe board 1118 as an intermediary to provide the networking interface. Memory/storage components 1206 may provide persistent and/or volatile storage. For example, memory/storage components 1206 may include dynamic random-access memory (DRAM), persistent Flash storage (e.g., NAND), and/or combinations of persistent and volatile storage. Boat lobe board 1200 may receive power via power connector 1214 in a form that is suitable for power distribution within a module (e.g., DC power at a fixed voltage within an approximate range of 12 to 400 V DC). Boat power converter 1208 may be configured to convert this received power into one or more different forms (e.g., DC power at a fixed voltage within an approximate range of 0.5 to 2.5 V DC) that may be used directly by processing components 1204 and memory/storage components 1206.

There are many types of alternative embodiments of a boat lobe board. For example, in a first type of alternative embodiment, one or more components (e.g., one or more power converters, memory/storage components, and/or networking components) may be shared among one or more nodes located on a first side of the PCB, and/or one or more nodes located on a second side of the PCB. In a second type of alternative embodiment, components may be mounted on only one side of the PCB. In a third type of alternative embodiment, each of two sides of the PCB may have zero or more processing, memory/storage, networking, and power conversion components, and all of the components on both sides of the PCB may form a single node. In a fourth type of alternative embodiment, one or more of the individual components on the PCB may integrate multiple functions, e.g., one or more of processing, memory/storage, networking, and power conversion. These and other types of alternative embodiments may be combined in various ways to enable a variety of possible boat lobe board configurations.

In some embodiments, one or more TIM layers, heat risers, and/or other thermal-management elements may be attached to one or more of the components on a component side of a PCB (e.g., PCB 1202) such that all of the significant heat-dissipating components on that side of the PCB collectively define a heat-rejection plane. The heat-rejection plane, for example, may be implemented when a cooling element 106 is also substantially planar, to maximize the total aggregate thermal contact area between the components and cooling element 106. For example, heat riser 1220 may be disposed on memory/storage components 1206 such that memory/storage components 1206 and processing component 1204 (e.g., the tallest component on boat lobe board 1200) define heat-rejection plane 1222. When a component (e.g., processing component 1204) natively has a surface in the heat-rejection plane (e.g., heat-rejection plane 1222) that is sufficient for cooling the component via thermal coupling with cooling element 106, the need to attach to the component one or more TIM layers, heat risers, and/or other thermal-management elements, for the purpose of moving heat from the component to the heat-rejection plane, may be reduced or eliminated.

Returning to FIG. 11, marina brain board assembly 1100 may further include module power connector 1122 and module network connector 1124. As discussed above, module power connector 1122 may be connected with the power distribution unit (e.g., power distribution unit 162 shown in FIGS. 1B, 1C and 2) via a power connector of a stackable frame (e.g., power connector 158 of stackable frame 102, as shown in FIG. 2). Module power connector 1122 may further be connected with each of power boards 1106a-1106d (e.g., via one or more power cables within marina brain board assembly 1100). As such, each of power boards 1106a-1106d may be configured to receive power in a form that is suitable for power distribution within a chassis (e.g., single-phase AC power at a fixed voltage of approximately 277 V AC, or DC power at a fixed voltage within an approximate range of 12 to 400 V DC), and then convert this received power into a form that is suitable for power distribution within a module (e.g., DC power at a fixed voltage within an approximate range of 12 to 400 V DC). As discussed above, the power output from power boards 1106a-1106d may then be converted (e.g., at the boat lobe board level) by each boat power converter 1208 into one or more different forms (e.g., DC power at a fixed voltage within an approximate range of 0.5 to 2.5 V DC) that may be used directly by components of the boat lobe boards 1118, including processing components 1204 and memory components 1206.

In some embodiments, each of power boards 1106a-1106d may be configured to convert power from the form delivered by module power connector 1122, into a form that may be used directly by components of the boat lobe boards 1118. Here, the boat lobe boards 1118 may not include boat power converters 1208.

In some embodiments, each of the boat power converters 1208 may be configured to convert power from the form delivered by module power connector 1122, into a form that may be used directly by components of the boat lobe boards 1118. Here, boardwalk board 1104 may receive power directly from module power connector 1122, and marina brain board assembly 1100 may not include power boards 1106a-1106d.

In some embodiments, boardwalk board 1104 may be configured to control the distribution of power from power boards 1106a-1106d to pier boards 1110a-1110d. For example, each of power boards 1106a-1106d may be connected with one of the pier boards 1110a-1110. In another example, pier boards 1110a-1110d may each share power distributed from one or more of power boards 1106 during normal system operation and/or in the event of a failure on one or more of power boards 1106. As such, failure of a power board 1106 may not necessarily cause all 16 boat lobe boards 1118 of a pier board 1110 to lose power.

Also as discussed above, module network connector 1124 may be connected with a network module (e.g., network module 500 shown in FIGS. 5A and 5B) via a network connector of the stackable frame (e.g., network connector 160 of stackable frame 102, as shown in FIG. 2). Module network connector 1124 may further be connected with network switch/router board 1108 (e.g., via one or more data cables within marina brain board assembly 1100). Network switch/router board 1108 may be configured to receive data from the network module (e.g., via the 32 input links of cable 502 shown in FIG. 5B), and then send these data to the boat lobe boards 1118 (e.g., via boardwalk board 1104, pier boards 1110, and boat connectors 1120). Network switch/router board 1108 may further be configured to receive data from the boat lobe boards 1118 (e.g., via boat connectors 1120, pier boards 1110, and boardwalk board 1104), and then send these data to other modules and/or external components (e.g., via the 32 output links of cable 502 shown in FIG. 5A).

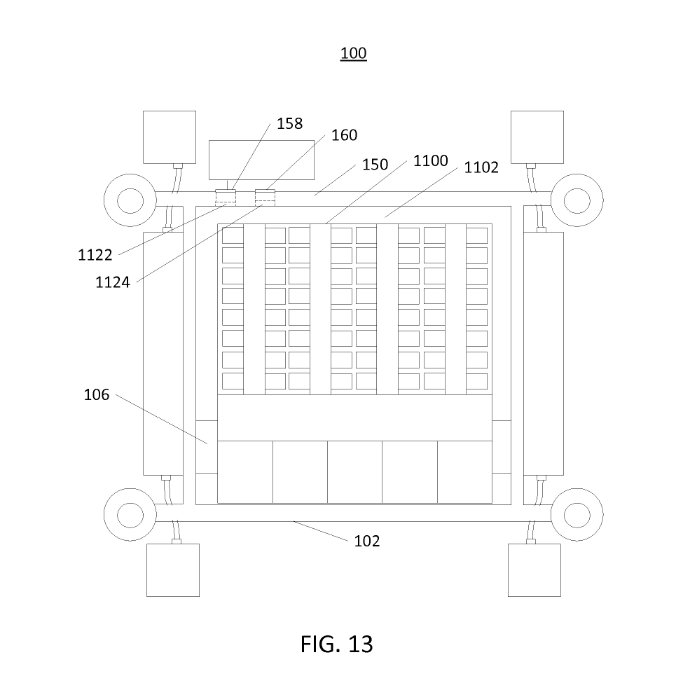

FIG. 13 shows a cross sectional view of cooling system 100 taken along line AA shown in FIG. 1A and including marina brain board assembly 1100 disposed therein, in accordance with some embodiments. Module frame 1102 may be fit within frame 150 of stackable frame 102, to mechanically stabilize marina brain board assembly 1100 within stackable frame 102. Module power connector 1122 may be connected with power connector 158, and module network connector 1124 may be connected with network connector 160. Furthermore, the bottom of marina brain board assembly 1100 (e.g., including components disposed on the bottom of lobe boat boards 1118, pier boards 1110a-1110d, power boards 1106a-1106d, marina board 1104, and/or network switch/router board 1108) may be in mechanical and thermal contact with cooling elements 106, to provide cooling to marina brain board assembly 1100.

Some embodiments may be designed to provide for variations in design and/or configuration of boards within a single marina brain board assembly 1100. Such embodiments may include a uniform board external-interface specification for each of one of more board types (e.g., boardwalk board 1104, power boards 1106, network switch/router board 1108, pier boards 1110, and/or boat lobe boards 1118). Each of the boards that are installed in a marina brain board assembly 1100 may then be required to conform to a specification corresponding to the board's type. Each such specification may include constraints on external mechanical, thermal, electrical, and/or communication-protocol characteristics, and/or other design and/or configuration parameters. Within these constraints, the boards of each type that are installed in a marina brain board assembly 1100 may individually vary widely in functional capabilities, performance, capacity, power/cooling requirements, internal architecture, component-technology generations, manufacturing cost, and/or other characteristics. This ability to combine multiple designs and/or configurations of boards in a single marina brain board assembly 1100 may be advantageous for optimizing system configurations to meet specific application requirements. Additionally or alternatively, during the operational lifetime of a specific marina brain board assembly 1100, which may span many years, developments may favor replacement of certain hardware elements. Examples may include failures within individual elements; availability of improved designs for certain elements; and/or changes in application requirements. In some cases, such a development may affect only a subset of the elements in a specific existing marina brain board assembly 1100. For example, certain processor components in a marina brain board assembly 1100 may become effectively obsolete within 12-18 months after deployment, whereas time to obsolescence for certain power-conversion components within the same marina brain board assembly 1100 may be many years. In such cases, it may be possible to make the desired hardware changes by replacing a subset of the boards in an existing marina brain board assembly 1100, thereby reducing unnecessary component replacements.

As an example of variations in design and/or configuration of boards within a single marina brain board assembly 1100, and with reference to FIG. 11, a marina brain board assembly 1100 may be designed to accommodate concurrently a set of boat lobe boards that each independently conform to one of a set of multiple boat lobe board sizes. For each boat lobe board size, multiple boat lobe board designs and/or configurations may also be accommodated. The minimum boat lobe board size may be the size of a boat lobe board 1118 as shown in FIG. 11. Each of a set of one or more larger boat lobe board sizes may be designed to occupy space along a pier board 1110 that could otherwise be occupied by a larger number (e.g., between two and eight) of individual minimum-size boat lobe boards 1118. A boat lobe board conforming to one of these larger sizes may include multiple pier connectors 1210, for making power and networking connections to multiple boat connectors 1120 along a pier board 1110. Each of an additional set of one or more larger boat lobe board sizes may be designed to occupy space that could otherwise be occupied by one or more complete pier assemblies (e.g., between one and four), each comprising a pier board 1110 and sixteen minimum-size boat lobe boards attached to the pier board 1110. A boat lobe board conforming to one of these larger sizes may not include any pier connectors 1210 for making power and networking connections to a boat connector 1120 along a pier board. Such a boat lobe board may instead include one or more connectors that are each designed to make power and networking connections to a pier connector 1116 on boardwalk board 1104, in place of a pier board 1110. In general, this ability to accommodate larger boat lobe board sizes may be advantageous when implementing functionality on a boat lobe board that requires more resources (e.g., PCB area, power/cooling capacity, and/or network connectivity) than a single minimum-size boat lobe board 1118 could provide.

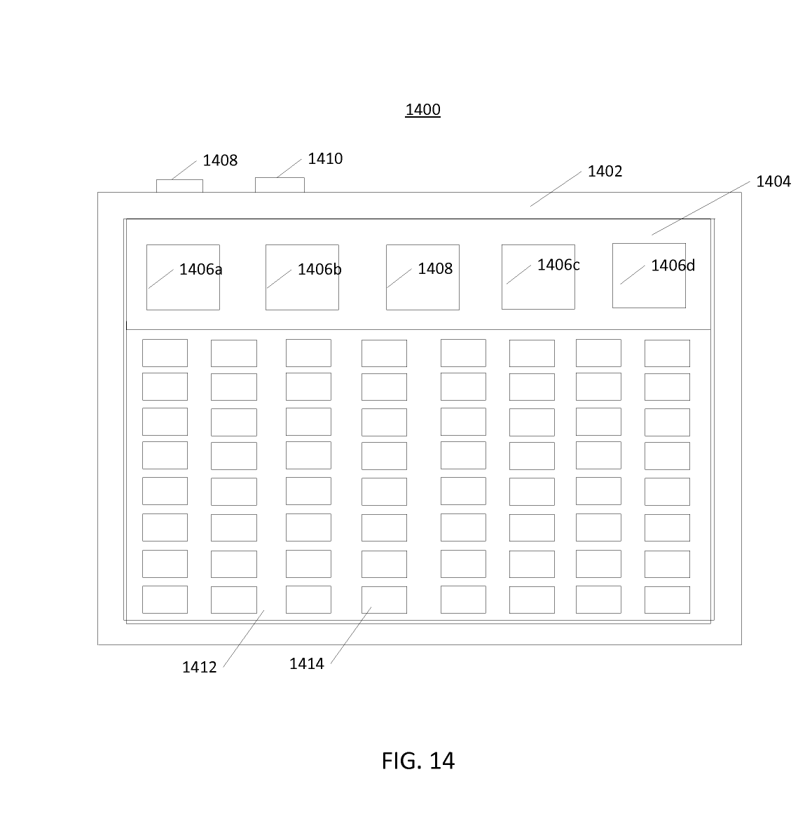

FIG. 14 shows a top view of an example brain board assembly 1400, in accordance with some embodiments. Brain board assembly 1400 may be another example of a module that may be placed within a stackable frame, such as module 104 shown in FIG. 1A. Brain board assembly 1400 may include frame 1402 and brain board 1404 that includes power components 1406a-1406d and network component 1408, which may be similar to power components 1106a-1106d and network component 1108 of marina brain board assembly 1100 shown in FIG. 11. Brain board 1404 may further include (e.g., integrated to the PCB) brain power connector 1408 and brain network connector 1410, configured to connect with a power connector and a network connector of a stackable shelf frame. As such, the need for internal cables, which may be used within marina brain board assembly 1100 as described above to carry power and/or data, may be reduced or eliminated in brain board assembly 1400.

Furthermore, brain board assembly 1400 may not include the pier boards and boat lobe boards of marina brain board assembly 1100. Instead, brain board assembly 1400 may include a lobe board 1412, which may be a PCB with components disposed on each of two sides. Sixty four lobe units 1414 may be disposed on each side of lobe board 1412, for a total of 128 lobe units 1414. In some embodiments, each lobe component 1414 may include a processing component and one or more (e.g., four) memory/storage components. The use of a single lobe board 1412, instead of multiple pier boards and boat lobe boards, may reduce manufacturing costs, at the expense of also reducing the serviceability of brain board assembly 1400 (e.g., relative to marina brain board assembly 1100).

As described above, in some embodiments of module 104 it may be advantageous to implement one or more PCBs that have components disposed on each of two sides. In some cases, certain considerations may reduce the benefits of such an implementation. As one example, a component disposed on one side of a PCB might require a mechanical backing plate disposed in a corresponding location on an opposite side of the PCB, which may greatly reduce the total area on the opposite side of the PCB that is available for other components. In such cases, it may be more advantageous to implement one or more alternative PCB configurations. One example of such an alternative PCB configuration may include a coupled pair of PCBs. The coupling between the pair of PCBs may include one or more connections, each of which may include mechanical, thermal, electrical, data-communication, and/or other types of elements. Each of the coupled pair of PCBs may have a “primary” side that may include one or more components of any type, and an opposite “secondary” side that may include zero or more components, each of which may be limited to a relatively small maximum size and/or a relatively small maximum heat dissipation. The coupled pair of PCBs may be disposed such that the secondary sides of the PCBs face toward each other, and the primary sides of the PCBs face away from each other.

As discussed above, marina brain board assembly 1100 and brain board assembly 1400 are examples of modules that may be placed within a stackable frame to receive two-sided cooling, such as module 104 shown in FIG. 1A. However, module 104 is not limited to such assemblies, and may be any other type of module containing any set of components that may perform any set of functions, including data networking, processing, storage, and/or any other types of functions. Some other suitable examples of module 104 are discussed in U.S. patent application Ser. No. 13/844,863, titled “Stackable Computing System,” which is hereby incorporated by reference herein in its entirety.

Some embodiments may be designed to provide for variations in design, functionality, capability, and/or configuration of modules 104 within a single cooling system 100. Such embodiments may include a uniform module external-interface specification, to which all of the modules 104 that are installed in a cooling system 100 must conform. This specification may include constraints on external mechanical, thermal, electrical, and/or communication-protocol characteristics, and/or other design and/or configuration parameters. Within these constraints, the modules 104 that are installed in a cooling system 100 may individually vary widely in functional capabilities, performance, capacity, power/cooling requirements, internal architecture, component-technology generations, manufacturing cost, and/or other characteristics. For example, one or more of the modules 104 that are installed in a cooling system 100 may be based on the marina brain board assembly architecture described above, and other modules 104 installed in the same cooling system 100 may be based on different internal architectures. This ability to combine multiple designs and/or configurations of modules 104 in a single cooling system 100 may be advantageous for optimizing system configurations to meet specific application requirements. Additionally or alternatively, during the operational lifetime of a specific cooling system 100, which may span many years, developments may favor replacement of certain hardware elements. Examples may include failures within individual elements; availability of improved designs for certain elements; and/or changes in application requirements. In some cases, such a development may affect only a subset of the elements in a specific existing cooling system 100. For example, certain functional components in a cooling system 100 may become effectively obsolete within 12-18 months after deployment, whereas time to obsolescence for other elements within the same cooling system 100 (e.g., cooling elements 106) may be many years. In such cases, it may be possible to make the desired hardware changes by replacing a subset of the installed modules 104 in an existing cooling system 100, thereby reducing unnecessary component replacements.

Some embodiments of cooling system 100 in which cooling elements 106 include vapor chambers and/or similar structures, may be particularly well suited to support variations in internal design and/or configuration among installed modules 104. Relative to comparable configurations of other known types of cooling elements, a vapor chamber or similar structure may provide a more uniform cooling capability across its exterior surfaces. This may be advantageous when deploying a cooling system 100 with stackable frames 102 and cooling elements 106 that each may over a multiple-year operational lifetime be required to accommodate a series of modules 104 that may vary in internal design and/or configuration. For each such module 104, the specific number, positions, sizes, and/or thermal characteristics of the module's internal heat-dissipating components may not be known in advance when cooling system 100 is deployed in an initial configuration. Accordingly, it may be beneficial to include vapor chambers and/or similar structures in the design of cooling elements 106, in preference over other known types of cooling elements, which may be most effective only when custom-configured according to a specific known and fixed configuration of heat-dissipating components.

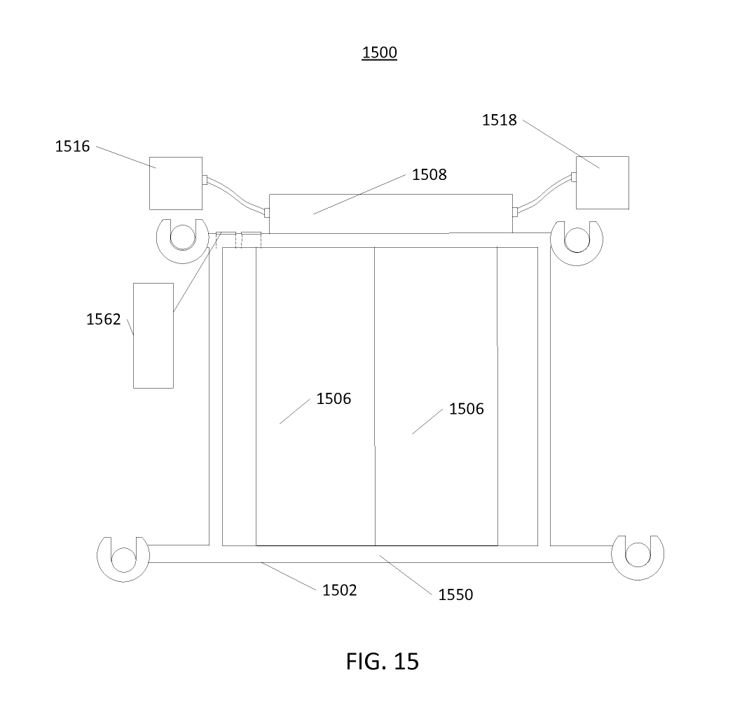

In various embodiments, one or more cooling rails may be placed at locations other than the sides of a stackable frame (e.g., as shown in FIGS. 1A, 1B, 1C and 2). FIG. 15 shows a cross sectional top view of an example stackable cooling rail based system 1500 (or cooling system 1500), in accordance with some embodiments. For example, cooling rail 1508 may be coupled mechanically with the back of stackable frame 1502. Power distribution unit 1562 may be located at a side or some other area of cooling system 1500 to make room for cooling rail 1508. Furthermore, cooling system 1500, having only a single cooling rail 1508 for each stackable frame, may utilize a single inlet cooling fluid manifold 1516 and a single outlet cooling fluid manifold 1518 to provide cooling fluid flow through cooling rail 1508 of each stackable frame.

In some embodiments, the one or more cooling elements of each stackable frame may include any combination of vapor chambers, cooling plates, heat pipes, and/or any other suitable structures that are capable of two-sided thermal coupling with modules. Example heat pipes, cooling plates, and corresponding stackable frame designs are discussed in greater detail in U.S. patent application Ser. No. 13/844,863, titled “Stackable Computing System,” incorporated by reference above. Additional details regarding cooling plates, applicable to some embodiments, are discussed in greater detail in U.S. Patent Publication No. 2012/0020024, titled “Cooled Universal Hardware Platform,” which is hereby incorporated by reference in its entirety.

Many modifications and other embodiments will come to mind to one skilled in the art to which these embodiments pertain having the benefit of the teachings presented in the foregoing descriptions and the associated drawings. Therefore, it is to be understood that embodiments and implementations are not to be limited to the specific example embodiments disclosed, and that modifications and other embodiments are intended to be included within the scope of the appended claims. Although specific terms are employed herein, they are used in a generic and descriptive sense only and not for purposes of limitation.

That which is claimed:

1. A stackable cooling rail based system, comprising:
a plurality of stackable frames, each of the stackable frames including:
a module receiving area;
a cooling element configured to couple thermally with one of a first side and a second side of a module when the module is located in the module receiving area; and
one or more cooling rails coupled thermally with the cooling element; and wherein:
the plurality of stackable frames are adjustable between a stacked configuration and an opened configuration;
in the stacked configuration, the plurality of stackable frames are stacked together; and
in the opened configuration, at least one pair of consecutively stacked stackable frames of the plurality of stackable frames, are separated by an access gap.

2. The stackable cooling rail based system of claim 1, wherein the one or more cooling rails of each stackable frame each conform to a distance defined by their stackable frame.

3. The stackable cooling rail based system of claim 1 further comprising an inlet cooling fluid manifold to provide cooling fluid to at least one of the one or more cooling rails of each stackable frame.

4. The stackable cooling rail based system of claim 3, wherein the inlet cooling fluid manifold is connected with the at least one of the one or more cooling rails via a flexible connection.

5. The stackable cooling rail based system of claim 1 further comprising an outlet cooling fluid manifold to receive cooling fluid from at least one of the one or more cooling rails of each stackable frame.

6. The stackable cooling rail based system of claim 5, wherein the outlet cooling fluid manifold is connected with the at least one of the one or more cooling rails via a flexible connection.

7. The stackable cooling rail based system of claim 1, wherein the cooling element of each stackable frame is a vapor chamber.

8. The stackable cooling rail based system of claim 1, wherein each of the one or more cooling rails of each stackable frame includes one or more fluid channels for cooling fluid flow.

9. The stackable cooling rail based system of claim 1, wherein each of the one or more cooling rails of each stackable frame includes a slot for thermal coupling with the cooling element of each stackable frame.

10. The stackable cooling rail based system of claim 1, wherein each of the plurality of stackable frames further includes a second cooling element coupled thermally with the one of the first side and the second side of the module and the one or more cooling rails.

11. The stackable cooling rail based system of claim 1 further comprising the module and wherein:
the module includes one or more printed circuit board assemblies that collectively define an outer surface of the module on at least one of the first side and the second side of the module; and
one or more components are disposed on each of two sides of the one or more printed circuit board assemblies.

12. The stackable cooling rail based system of claim 1, further comprising a chassis including one or more chassis poles and wherein:
each of the one or more chassis poles is disposed substantially parallel to a stacking axis; and
each stackable frame includes one or more frame spacers, each including a chassis pole hole to receive a chassis pole of the one or more chassis poles; and
the one or more cooling rails of each stackable frame may move together with their stackable frame along the stacking axis defined by the one or more chassis poles.

13. The stackable cooling rail based system of claim 1, wherein the one or more cooling rails of each of the plurality of stackable frames includes a first cooling rail and a second cooling rail coupled thermally with the cooling element at opposite sides of the cooling element.

14. The stackable cooling rail based system of claim 1, wherein the cooling element of each stackable frame is a vapor chamber including a non-planar profile.

15. The stackable cooling rail based system of claim 1, wherein the access gap is configured to provide physical access to a module.

16. A stackable cooling rail based system, comprising:
a plurality of stackable frames, at least one stackable frame including:
a frame defining a module receiving area;
one or more vapor chambers coupled mechanically with the at least one stackable frame for thermal coupling with one or more modules located in the module receiving area; and
one or more cooling rails coupled thermally with the one or more vapor chambers and coupled mechanically with the at least one stackable frame such that the one or more cooling rails is configured to move together with the at least one stackable frame.

17. The stackable cooling rail based system of claim 16, wherein at least one of the one or more cooling rails of the at least one stackable frame is configured to conform to a distance defined by a combined thickness of the module receiving area and at least one of the one or more vapor chambers.

18. The stackable cooling rail based system of claim 16, wherein at least one of the one or more cooling rails of the at least one stackable frame includes one or more fluid channels for cooling fluid flow.

19. A stackable cooling rail based system, comprising:
a plurality of stackable frames, at least one stackable frame including:
one or more modules, at least one module including one or more printed circuit board assemblies that collectively define at least one of a first and second outer surface of the at least one module, and each of the printed circuit board assemblies having components disposed on one or more sides;
one or more vapor chambers coupled thermally with one of a first side and a second side of at least one of the one or more modules;
one or more cooling rails coupled thermally with at least one of the one or more vapor chambers; and
one or more inlet cooling fluid manifolds to provide cooling fluid to at least one of the one or more cooling rails of the at least one stackable frame; and
one or more outlet cooling fluid manifolds to receive cooling fluid from the at least one of the one or more cooling rails of the at least one stackable frame; and
wherein:
the plurality of stackable frames are adjustable between a stacked configuration and an opened configuration;
in the stacked configuration, the plurality of stackable frames are stacked together; and
in the opened configuration, at least one pair of consecutively stacked stackable frames of the plurality of stackable frames, are separated by an access gap.

20. The stackable cooling rail based system of claim 19, wherein at least one of the one or more cooling rails of the at least one stackable frame is configured to conform to a distance defined by a combined thickness of at least one of the one or more modules of the at least one stackable frame and at least one of the one or more vapor chambers of the at least one stackable frame.
